(19) United States
(12) Patent Application Publication
(10) Pub. No.: US 2025/0123339 A1
(43) Pub. Date: Apr. 17, 2025

(54) MAGNETIC FIELD REPORT FOR UE ORIENTATION / LOCATION ESTIMATION

(71) Applicant: QUALCOMM Incorporated, San Diego, CA (US)

(72) Inventors: Jingchao BAO, San Diego, CA (US); Sony AKKARAKARAN, Poway, CA (US); Tao LUO, San Diego, CA (US)

(21) Appl. No.: 18/487,732

(22) Filed: Oct. 16, 2023

(51) Int. Cl. G01R 33/02; H04W 64/00

(52) U.S. Cl. CPC G01R 33/0206; H04W 64/00

(57) ABSTRACT

An apparatus that may be a wireless device. The apparatus configured to obtain an indication of a location of the wireless device, measure a magnetic field at the location of the wireless device, and output, for a network device, information regarding the location of the wireless device and the measured magnetic field at the location of the wireless device. An apparatus that may be a network device. The apparatus configured to obtain one or more sets of information regarding one or more magnetic field measurements at one or more wireless devices, generate, based on the one or more sets of information, a mapping of positions in space to magnetic field information, and output, for at least one wireless device, mapping information based on the mapping of the positions.

### TECHNICAL FIELD

The present disclosure relates generally to communication systems, and more particularly, to positioning and orientation operation at a wireless device.

### INTRODUCTION

Wireless communication systems are widely deployed to provide various telecommunication services such as telephony, video, data, messaging, and broadcasts. Typical wireless communication systems may employ multiple-access technologies capable of supporting communication with multiple users by sharing available system resources. Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example telecommunication standard is 5G New Radio (NR). 5G NR is part of a continuous mobile broadband evolution promulgated by Third Generation Partnership Project (3GPP) to meet new requirements associated with latency, reliability, security, scalability (e.g., with Internet of Things (IoT)), and other requirements. 5G NR includes services associated with enhanced mobile broadband (eMBB), massive machine type communications (mMTC), and ultra-reliable low latency communications (URLLC). Some aspects of 5G NR may be based on the 4G Long Term Evolution (LTE) standard. There exists a need for further improvements in 5G NR technology. These improvements may also be applicable to other multi-access technologies and the telecommunication standards that employ these technologies.

### BRIEF SUMMARY

The following presents a simplified summary of one or more aspects in order to provide a basic understanding of such aspects. This summary is not an extensive overview of all contemplated aspects. This summary neither identifies key or critical elements of all aspects nor delineates the scope of any or all aspects. Its sole purpose is to present some concepts of one or more aspects in a simplified form as a prelude to the more detailed description that is presented later.

In an aspect of the disclosure, a method, a computer-readable medium, and an apparatus are provided. The apparatus, in some aspects, may be a wireless device configured to obtain an indication of a location of the wireless device, measure a magnetic field at the location of the wireless device, and output, for a network device, information regarding the location of the wireless device and the measured magnetic field at the location of the wireless device.

In an aspect of the disclosure, a method, a computer-readable medium, and an apparatus are provided. The apparatus, in some aspects, may be a wireless device configured to obtain one or more sets of information regarding one or more magnetic field measurements at one or more wireless devices, generate, based on the one or more sets of information, a mapping of positions in space to magnetic field information, and output, for at least one wireless device, mapping information based on the mapping of the positions.

To the accomplishment of the foregoing and related ends, the one or more aspects may include the features hereinafter fully described and particularly pointed out in the claims. The following description and the drawings set forth in detail certain illustrative features of the one or more aspects. These features are indicative, however, of but a few of the various ways in which the principles of various aspects may be employed.

### BRIEF DESCRIPTION OF THE DRAWINGS

FIG. 1 is a diagram illustrating an example of a wireless communications system and an access network.

FIG. 2A is a diagram illustrating an example of a first frame, in accordance with various aspects of the present disclosure.

FIG. 2B is a diagram illustrating an example of downlink (DL) channels within a subframe, in accordance with various aspects of the present disclosure.

FIG. 2C is a diagram illustrating an example of a second frame, in accordance with various aspects of the present disclosure.

FIG. 2D is a diagram illustrating an example of uplink (UL) channels within a subframe, in accordance with various aspects of the present disclosure.

FIG. 3 is a diagram illustrating an example of a base station and user equipment (UE) in an access network.

FIG. 4 is a diagram illustrating large-scale fluctuations in magnetic field strength and direction that may be used in accordance with some aspects of the disclosure.

FIG. 5 is a diagram illustrating a magnetic field measurement deviating from an expected magnetic field in the presence of a local magnetic field, in accordance with some aspects of the disclosure.

FIG. 6 is a diagram illustrating a mapping of magnetic fields by region for regions defined at different levels of a hierarchy in accordance with some aspects of the disclosure.

FIG. 7 is a call flow diagram illustrating a method of wireless communication associated with reporting magnetic field information to a network in accordance with some aspects of the disclosure.

FIG. 8 is a call flow diagram illustrating a method of wireless communication associated with using reported magnetic field information to generate a magnetic field mapping at a network in accordance with some aspects of the disclosure.

FIG. 9 is a call flow diagram illustrating a method of wireless communication associated with using magnetic field information to determine a location in accordance with some aspects of the disclosure.

FIG. 10 is a diagram that illustrates two candidate trajectories between a first contour line associated with a first magnetic field strength and a second contour line having a second magnetic field strength in accordance with some aspects of the disclosure.

FIG. 11 is a flowchart of a method of wireless communication.

FIG. 12 is a flowchart of a method of wireless communication.

FIG. 13 is a flowchart of a method of wireless communication.

FIG. 14 is a flowchart of a method of wireless communication.

FIG. 15 is a diagram illustrating an example of a hardware implementation for an example apparatus and/or network entity.

FIG. 16 is a diagram illustrating an example of a hardware implementation for an example network entity.

FIG. 17 is a diagram illustrating an example of a hardware implementation for an example network entity.

### DETAILED DESCRIPTION

A wireless device, in some aspects, may include an inertial measurement unit (IMU) used in determining a location and orientation of the device. A magnetometer, in some aspects, may be a component of the IMU and may provide the magnetic north (or south) direction. Combined with other measurements, the mobile device may estimate its orientation and or positioning using sensor fusion (e.g., Kalman filtering). Given a rough location estimation, a wireless device or UE may obtain an indication of a local magnetic field direction (e.g., a vector indicating a magnetic north or south) from a database and use the indicated direction for determining a location and/or orientation of the wireless device or UE.

In an open space, this usually works well. However, in a complex environment with many magnetic materials, the local magnetic field may be distorted and may not match the magnetic field direction indicated in the database. This will cause orientation and/or positioning errors. For example, a sensor fusion algorithm may not converge and may trigger a warning regarding an unreliability and/or a large uncertainty of an associated orientation and/or positioning determination. Therefore, a high resolution magnetic field database may provide for robust sensor fusion (e.g., for orientation estimation and/or positioning) in a complex environment (e.g., in an indoor office).

Various aspects relate generally to reporting magnetic field information from one or more wireless devices to a network device for the network device to generate a high resolution magnetic field database that can be used by the wireless device to perform an orientation and/or positioning operation. Some aspects more specifically relate to a wireless device that obtains an indication of a location of the wireless device, measures a magnetic field at the location of the wireless device, and outputs, for a network device, information regarding the location of the wireless device and the measured magnetic field at the location of the wireless device. Some aspects relate to a network device that obtains one or more sets of information regarding one or more magnetic field measurements at one or more wireless devices, generates, based on the one or more sets of information, a mapping of positions in space to magnetic field information, and outputs, for at least one wireless device, mapping information based on the mapping of the positions.

Particular aspects of the subject matter described in this disclosure can be implemented to realize one or more of the following potential advantages. In some examples, by providing magnetic field information from at least one wireless device to a network device and generating and/or providing a mapping of the magnetic field to one or more wireless devices, the described techniques can be used to improve the accuracy of an orientation and/or positioning operation.

The detailed description set forth below in connection with the drawings describes various configurations and does not represent the only configurations in which the concepts described herein may be practiced. The detailed description includes specific details for the purpose of providing a thorough understanding of various concepts. However, these concepts may be practiced without these specific details. In some instances, well known structures and components are shown in block diagram form in order to avoid obscuring such concepts.

Several aspects of telecommunication systems are presented with reference to various apparatus and methods. These apparatus and methods are described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. When multiple processors are implemented, the multiple processors may perform the functions individually or in combination. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software, whether referred to as software, firmware, middleware, microcode, hardware description language, or otherwise, shall be construed broadly to mean instructions, instruction sets, code, code segments, program code, programs, subprograms, software components, applications, software applications, software packages, routines, subroutines, objects, executables, threads of execution, procedures, functions, or any combination thereof.

Accordingly, in one or more example aspects, implementations, and/or use cases, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, such computer-readable media can include a random-access memory (RAM), a read-only memory (ROM), an electrically erasable programmable ROM (EEPROM), optical disk storage, magnetic disk storage, other magnetic storage devices, combinations of the types of computer-readable media, or any other medium that can be used to store computer executable code in the form of instructions or data structures that can be accessed by a computer.

While aspects, implementations, and/or use cases are described in this application by illustration to some examples, additional or different aspects, implementations and/or use cases may come about in many different arrangements and scenarios. Aspects, implementations, and/or use cases described herein may be implemented across many differing platform types, devices, systems, shapes, sizes, and packaging arrangements. For example, aspects, implementations, and/or use cases may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described examples may occur. Aspects, implementations, and/or use cases may range a spectrum from chip-level or modular components to non-modular, non-chip-level implementations and further to aggregate, distributed, or original equipment manufacturer (OEM) devices or systems incorporating one or more techniques herein. In some practical settings, devices incorporating described aspects and features may also include additional components and features for implementation and practice of claimed and described aspect. For example, transmission and reception of wireless signals necessarily includes a number of components for analog and digital purposes (e.g., hardware components including antenna, RF-chains, power amplifiers, modulators, buffer, processor(s), interleaver, adders/summers, etc.). Techniques described herein may be practiced in a wide variety of devices, chip-level components, systems, distributed arrangements, aggregated or disaggregated components, end-user devices, etc. of varying sizes, shapes, and constitution.

Deployment of communication systems, such as 5G NR systems, may be arranged in multiple manners with various components or constituent parts. In a 5G NR system, or network, a network node, a network entity, a mobility element of a network, a radio access network (RAN) node, a core network node, a network element, or a network equipment, such as a base station (BS), or one or more units (or one or more components) performing base station functionality, may be implemented in an aggregated or disaggregated architecture. For example, a BS (such as a Node B (NB), evolved NB (eNB), NR BS, 5G NB, access point (AP), a transmission reception point (TRP), or a cell, etc.) may be implemented as an aggregated base station (also known as a standalone BS or a monolithic BS) or a disaggregated base station.

An aggregated base station may be configured to utilize a radio protocol stack that is physically or logically integrated within a single RAN node. A disaggregated base station may be configured to utilize a protocol stack that is physically or logically distributed among two or more units (such as one or more central or centralized units (CUs), one or more distributed units (DUs), or one or more radio units (RUs)). In some aspects, a CU may be implemented within a RAN node, and one or more DUs may be co-located with the CU, or alternatively, may be geographically or virtually distributed throughout one or multiple other RAN nodes. The DUs may be implemented to communicate with one or more RUs. Each of the CU, DU and RU can be implemented as virtual units, i.e., a virtual central unit (VCU), a virtual distributed unit (VDU), or a virtual radio unit (VRU).

Base station operation or network design may consider aggregation characteristics of base station functionality. For example, disaggregated base stations may be utilized in an integrated access backhaul (IAB) network, an open radio access network (O-RAN (such as the network configuration sponsored by the O-RAN Alliance)), or a virtualized radio access network (vRAN, also known as a cloud radio access network (C-RAN)). Disaggregation may include distributing functionality across two or more units at various physical locations, as well as distributing functionality for at least one unit virtually, which can enable flexibility in network design. The various units of the disaggregated base station, or disaggregated RAN architecture, can be configured for wired or wireless communication with at least one other unit.

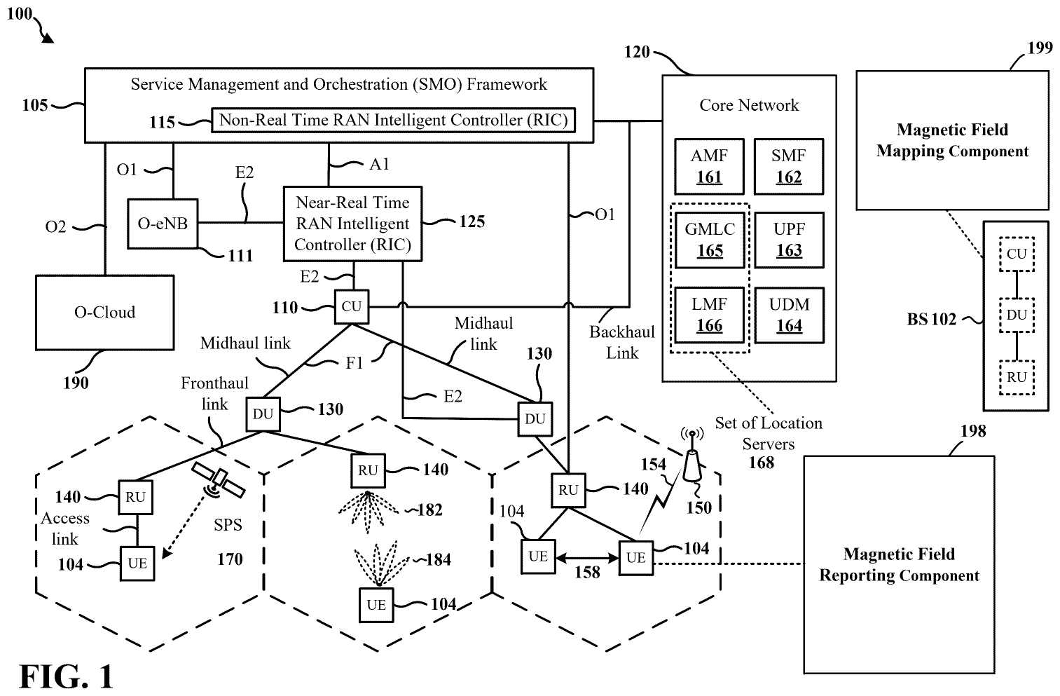

FIG. 1 is a diagram 100 illustrating an example of a wireless communications system and an access network. The illustrated wireless communications system includes a disaggregated base station architecture. The disaggregated base station architecture may include one or more CUs 110 that can communicate directly with a core network 120 via a backhaul link, or indirectly with the core network 120 through one or more disaggregated base station units (such as a Near-Real Time (Near-RT) RAN Intelligent Controller (RIC) 125 via an E2 link, or a Non-Real Time (Non-RT) RIC 115 associated with a Service Management and Orchestration (SMO) Framework 105, or both). A CU 110 may communicate with one or more DUs 130 via respective midhaul links, such as an F1 interface. The DUs 130 may communicate with one or more RUs 140 via respective fronthaul links. The RUs 140 may communicate with respective UEs 104 via one or more radio frequency (RF) access links. In some implementations, the UE 104 may be simultaneously served by multiple RUs 140.

Each of the units, i.e., the CUS 110, the DUs 130, the RUs 140, as well as the Near-RT RICs 125, the Non-RT RICs 115, and the SMO Framework 105, may include one or more interfaces or be coupled to one or more interfaces configured to receive or to transmit signals, data, or information (collectively, signals) via a wired or wireless transmission medium. Each of the units, or an associated processor or controller providing instructions to the communication interfaces of the units, can be configured to communicate with one or more of the other units via the transmission medium. For example, the units can include a wired interface configured to receive or to transmit signals over a wired transmission medium to one or more of the other units. Additionally, the units can include a wireless interface, which may include a receiver, a transmitter, or a transceiver (such as an RF transceiver), configured to receive or to transmit signals, or both, over a wireless transmission medium to one or more of the other units.

In some aspects, the CU 110 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 110. The CU 110 may be configured to handle user plane functionality (i.e., Central Unit-User Plane (CU-UP)), control plane functionality (i.e., Central Unit-Control Plane (CU-CP)), or a combination thereof. In some implementations, the CU 110 can be logically split into one or more CU-UP units and one or more CU-CP units. The CU-UP unit can communicate bidirectionally with the CU-CP unit via an interface, such as an E1 interface when implemented in an O-RAN configuration. The CU 110 can be implemented to communicate with the DU 130, as necessary, for network control and signaling.

The DU 130 may correspond to a logical unit that includes one or more base station functions to control the operation of one or more RUs 140. In some aspects, the DU 130 may host one or more of a radio link control (RLC) layer, a medium access control (MAC) layer, and one or more high physical (PHY) layers (such as modules for forward error correction (FEC) encoding and decoding, scrambling, modulation, demodulation, or the like) depending, at least in part, on a functional split, such as those defined by 3GPP. In some aspects, the DU 130 may further host one or more low PHY layers. Each layer (or module) can be implemented with an interface configured to communicate signals with other layers (and modules) hosted by the DU 130, or with the control functions hosted by the CU 110.

Lower-layer functionality can be implemented by one or more RUs 140. In some deployments, an RU 140, controlled by a DU 130, may correspond to a logical node that hosts RF processing functions, or low-PHY layer functions (such as performing fast Fourier transform (FFT), inverse FFT (iFFT), digital beamforming, physical random access channel (PRACH) extraction and filtering, or the like), or both, based at least in part on the functional split, such as a lower layer functional split. In such an architecture, the RU(s) 140 can be implemented to handle over the air (OTA) communication with one or more UEs 104. In some implementations, real-time and non-real-time aspects of control and user plane communication with the RU(s) 140 can be controlled by the corresponding DU 130. In some scenarios, this configuration can enable the DU(s) 130 and the CU 110 to be implemented in a cloud-based RAN architecture, such as a vRAN architecture.

The SMO Framework 105 may be configured to support RAN deployment and provisioning of non-virtualized and virtualized network elements. For non-virtualized network elements, the SMO Framework 105 may be configured to support the deployment of dedicated physical resources for RAN coverage requirements that may be managed via an operations and maintenance interface (such as an O1 interface). For virtualized network elements, the SMO Framework 105 may be configured to interact with a cloud computing platform (such as an open cloud (O-Cloud) 190) to perform network element life cycle management (such as to instantiate virtualized network elements) via a cloud computing platform interface (such as an O2 interface). Such virtualized network elements can include, but are not limited to, CUs 110, DUs 130, RUs 140 and Near-RT RICs 125. In some implementations, the SMO Framework 105 can communicate with a hardware aspect of a 4G RAN, such as an open eNB (O-eNB) 111, via an O1 interface. Additionally, in some implementations, the SMO Framework 105 can communicate directly with one or more RUs 140 via an O1 interface. The SMO Framework 105 also may include a Non-RT RIC 115 configured to support functionality of the SMO Framework 105.

The Non-RT RIC 115 may be configured to include a logical function that enables non-real-time control and optimization of RAN elements and resources, artificial intelligence (AI)/machine learning (ML) (AI/ML) workflows including model training and updates, or policy-based guidance of applications/features in the Near-RT RIC 125. The Non-RT RIC 115 may be coupled to or communicate with (such as via an A1 interface) the Near-RT RIC 125. The Near-RT RIC 125 may be configured to include a logical function that enables near-real-time control and optimization of RAN elements and resources via data collection and actions over an interface (such as via an E2 interface) connecting one or more CUs 110, one or more DUs 130, or both, as well as an O-eNB, with the Near-RT RIC 125.

In some implementations, to generate AI/ML models to be deployed in the Near-RT RIC 125, the Non-RT RIC 115 may receive parameters or external enrichment information from external servers. Such information may be utilized by the Near-RT RIC 125 and may be received at the SMO Framework 105 or the Non-RT RIC 115 from non-network data sources or from network functions. In some examples, the Non-RT RIC 115 or the Near-RT RIC 125 may be configured to tune RAN behavior or performance. For example, the Non-RT RIC 115 may monitor long-term trends and patterns for performance and employ AI/ML models to perform corrective actions through the SMO Framework 105 (such as reconfiguration via 01) or via creation of RAN management policies (such as A1 policies).

At least one of the CU 110, the DU 130, and the RU 140 may be referred to as a base station 102. Accordingly, a base station 102 may include one or more of the CU 110, the DU 130, and the RU 140 (each component indicated with dotted lines to signify that each component may or may not be included in the base station 102). The base station 102 provides an access point to the core network 120 for a UE 104. The base station 102 may include macrocells (high power cellular base station) and/or small cells (low power cellular base station). The small cells include femtocells, picocells, and microcells. A network that includes both small cell and macrocells may be known as a heterogeneous network. A heterogeneous network may also include Home Evolved Node Bs (eNBs) (HeNBs), which may provide service to a restricted group known as a closed subscriber group (CSG). The communication links between the RUs 140 and the UEs 104 may include uplink (UL) (also referred to as reverse link) transmissions from a UE 104 to an RU 140 and/or downlink (DL) (also referred to as forward link) transmissions from an RU 140 to a UE 104. The communication links may use multiple-input and multiple-output (MIMO) antenna technology, including spatial multiplexing, beamforming, and/or transmit diversity. The communication links may be through one or more carriers. The base station 102/UEs 104 may use spectrum up to Y MHz (e.g., 5, 10, 15, 20, 100, 400, etc. MHz) bandwidth per carrier allocated in a carrier aggregation of up to a total of Yx MHz (x component carriers) used for transmission in each direction. The carriers may or may not be adjacent to each other. Allocation of carriers may be asymmetric with respect to DL and UL (e.g., more or fewer carriers may be allocated for DL than for UL). The component carriers may include a primary component carrier and one or more secondary component carriers. A primary component carrier may be referred to as a primary cell (PCell) and a secondary component carrier may be referred to as a secondary cell (SCell).

Certain UEs 104 may communicate with each other using device-to-device (D2D) communication link 158. The D2D communication link 158 may use the DL/UL wireless wide area network (WWAN) spectrum. The D2D communication link 158 may use one or more sidelink channels, such as a physical sidelink broadcast channel (PSBCH), a physical sidelink discovery channel (PSDCH), a physical sidelink shared channel (PSSCH), and a physical sidelink control channel (PSCCH). D2D communication may be through a variety of wireless D2D communications systems, such as for example, Bluetooth™ (Bluetooth is a trademark of the Bluetooth Special Interest Group (SIG)), Wi-Fi™ (Wi-Fi is a trademark of the Wi-Fi Alliance) based on the Institute of Electrical and Electronics Engineers (IEEE) 802.11 standard, LTE, or NR.

The wireless communications system may further include a Wi-Fi AP 150 in communication with UEs 104 (also referred to as Wi-Fi stations (STAs)) via communication link 154, e.g., in a 5 GHz unlicensed frequency spectrum or the like. When communicating in an unlicensed frequency spectrum, the UEs 104/AP 150 may perform a clear channel assessment (CCA) prior to communicating in order to determine whether the channel is available.

The electromagnetic spectrum is often subdivided, based on frequency/wavelength, into various classes, bands, channels, etc. In 5G NR, two initial operating bands have been identified as frequency range designations FR1 (410 MHz-7.125 GHZ) and FR2 (24.25 GHz-52.6 GHz). Although a portion of FR1 is greater than 6 GHz, FR1 is often referred to (interchangeably) as a “sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHZ-24.25 GHZ). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR2-2 (52.6 GHz-71 GHZ), FR4 (71 GHz-114.25 GHZ), and FR5 (114.25 GHz-300 GHz). Each of these higher frequency bands falls within the EHF band.

With the above aspects in mind, unless specifically stated otherwise, the term “sub-6 GHz” or the like if used herein may broadly represent frequencies that may be less than 6 GHz, may be within FR1, or may include mid-band frequencies. Further, unless specifically stated otherwise, the term “millimeter wave” or the like if used herein may broadly represent frequencies that may include mid-band frequencies, may be within FR2, FR4, FR2-2, and/or FR5, or may be within the EHF band.

The base station 102 and the UE 104 may each include a plurality of antennas, such as antenna elements, antenna panels, and/or antenna arrays to facilitate beamforming. The base station 102 may transmit a beamformed signal 182 to the UE 104 in one or more transmit directions. The UE 104 may receive the beamformed signal from the base station 102 in one or more receive directions. The UE 104 may also transmit a beamformed signal 184 to the base station 102 in one or more transmit directions. The base station 102 may receive the beamformed signal from the UE 104 in one or more receive directions. The base station 102/UE 104 may perform beam training to determine the best receive and transmit directions for each of the base station 102/UE 104. The transmit and receive directions for the base station 102 may or may not be the same. The transmit and receive directions for the UE 104 may or may not be the same.

The base station 102 may include and/or be referred to as a gNB, Node B, eNB, an access point, a base transceiver station, a radio base station, a radio transceiver, a transceiver function, a basic service set (BSS), an extended service set (ESS), a TRP, network node, network entity, network equipment, or some other suitable terminology. The base station 102 can be implemented as an integrated access and backhaul (IAB) node, a relay node, a sidelink node, an aggregated (monolithic) base station with a baseband unit (BBU) (including a CU and a DU) and an RU, or as a disaggregated base station including one or more of a CU, a DU, and/or an RU. The set of base stations, which may include disaggregated base stations and/or aggregated base stations, may be referred to as next generation (NG) RAN (NG-RAN).

The core network 120 may include an Access and Mobility Management Function (AMF) 161, a Session Management Function (SMF) 162, a User Plane Function (UPF) 163, a Unified Data Management (UDM) 164, one or more location servers 168, and other functional entities. The AMF 161 is the control node that processes the signaling between the UEs 104 and the core network 120. The AMF 161 supports registration management, connection management, mobility management, and other functions. The SMF 162 supports session management and other functions. The UPF 163 supports packet routing, packet forwarding, and other functions. The UDM 164 supports the generation of authentication and key agreement (AKA) credentials, user identification handling, access authorization, and subscription management. The one or more location servers 168 are illustrated as including a Gateway Mobile Location Center (GMLC) 165 and a Location Management Function (LMF) 166. However, generally, the one or more location servers 168 may include one or more location/positioning servers, which may include one or more of the GMLC 165, the LMF 166, a position determination entity (PDE), a serving mobile location center (SMLC), a mobile positioning center (MPC), or the like. The GMLC 165 and the LMF 166 support UE location services. The GMLC 165 provides an interface for clients/applications (e.g., emergency services) for accessing UE positioning information. The LMF 166 receives measurements and assistance information from the NG-RAN and the UE 104 via the AMF 161 to compute the position of the UE 104. The NG-RAN may utilize one or more positioning methods in order to determine the position of the UE 104. Positioning the UE 104 may involve signal measurements, a position estimate, and an optional velocity computation based on the measurements. The signal measurements may be made by the UE 104 and/or the base station 102 serving the UE 104. The signals measured may be based on one or more of a satellite positioning system (SPS) 170 (e.g., one or more of a Global Navigation Satellite System (GNSS), global position system (GPS), non-terrestrial network (NTN), or other satellite position/location system), LTE signals, wireless local area network (WLAN) signals, Bluetooth signals, a terrestrial beacon system (TBS), sensor-based information (e.g., barometric pressure sensor, motion sensor), NR enhanced cell ID (NR E-CID) methods, NR signals (e.g., multi-round trip time (Multi-RTT), DL angle-of-departure (DL-AoD), DL time difference of arrival (DL-TDOA), UL time difference of arrival (UL-TDOA), and UL angle-of-arrival (UL-AoA) positioning), and/or other systems/signals/sensors.

Examples of UEs 104 include a cellular phone, a smart phone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, a smart device, a wearable device, a vehicle, an electric meter, a gas pump, a large or small kitchen appliance, a healthcare device, an implant, a sensor/actuator, a display, or any other similar functioning device. Some of the UEs 104 may be referred to as IoT devices (e.g., parking meter, gas pump, toaster, vehicles, heart monitor, etc.). The UE 104 may also be referred to as a station, a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. In some scenarios, the term UE may also apply to one or more companion devices such as in a device constellation arrangement. One or more of these devices may collectively access the network and/or individually access the network.

Referring again to FIG. 1, in certain aspects, the UE 104 may have a magnetic field reporting component 198 that may be configured to obtain an indication of a location of the wireless device, measure a magnetic field at the location of the wireless device, and output, for a network device, information regarding the location of the wireless device and the measured magnetic field at the location of the wireless device. In certain aspects, the base station 102 may have a magnetic field mapping component 199 that may be configured to obtain one or more sets of information regarding one or more magnetic field measurements at one or more wireless devices, generate, based on the one or more sets of information, a mapping of positions in space to magnetic field information, and output, for at least one wireless device, mapping information based on the mapping of the positions. Although the following description may be focused on 5G NR, the concepts described herein may be applicable to other similar areas, such as LTE, LTE-A, CDMA, GSM, and other wireless technologies.

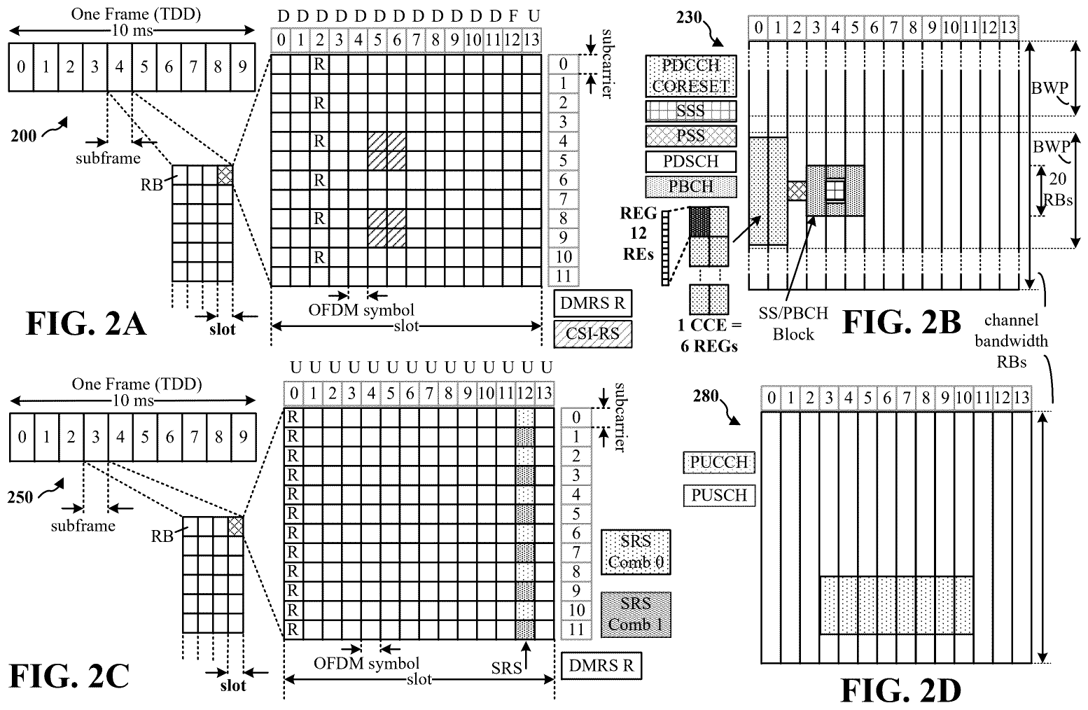

FIG. 2A is a diagram 200 illustrating an example of a first subframe within a 5G NR frame structure. FIG. 2B is a diagram 230 illustrating an example of DL channels within a 5G NR subframe. FIG. 2C is a diagram 250 illustrating an example of a second subframe within a 5G NR frame structure. FIG. 2D is a diagram 280 illustrating an example of UL channels within a 5G NR subframe. The 5G NR frame structure may be frequency division duplexed (FDD) in which for a particular set of subcarriers (carrier system bandwidth), subframes within the set of subcarriers are dedicated for either DL or UL, or may be time division duplexed (TDD) in which for a particular set of subcarriers (carrier system bandwidth), subframes within the set of subcarriers are dedicated for both DL and UL. In the examples provided by FIGS. 2A, 2C, the 5G NR frame structure is assumed to be TDD, with subframe 4 being configured with slot format 28 (with mostly DL), where D is DL, U is UL, and F is flexible for use between DL/UL, and subframe 3 being configured with slot format 1 (with all UL). While subframes 3, 4 are shown with slot formats 1, 28, respectively, any particular subframe may be configured with any of the various available slot formats 0-61. Slot formats 0, 1 are all DL, UL, respectively. Other slot formats 2-61 include a mix of DL, UL, and flexible symbols. UEs are configured with the slot format (dynamically through DL control information (DCI), or semi-statically/statically through radio resource control (RRC) signaling) through a received slot format indicator (SFI). Note that the description infra applies also to a 5G NR frame structure that is TDD.

FIGS. 2A-2D illustrate a frame structure, and the aspects of the present disclosure may be applicable to other wireless communication technologies, which may have a different frame structure and/or different channels. A frame (10 ms) may be divided into 10 equally sized subframes (1 ms). Each subframe may include one or more time slots. Subframes may also include mini-slots, which may include 7, 4, or 2 symbols. Each slot may include 14 or 12 symbols, depending on whether the cyclic prefix (CP) is normal or extended. For normal CP, each slot may include 14 symbols, and for extended CP, each slot may include 12 symbols. The symbols on DL may be CP orthogonal frequency division multiplexing (OFDM) (CP-OFDM) symbols. The symbols on UL may be CP-OFDM symbols (for high throughput scenarios) or discrete Fourier transform (DFT) spread OFDM (DFT-s-OFDM) symbols (for power limited scenarios; limited to a single stream transmission). The number of slots within a subframe is based on the CP and the numerology. The numerology defines the subcarrier spacing (SCS) (see Table 1). The symbol length/duration may scale with 1/SCS.

TABLE 1
Numerology, SCS, and CP

| | SCS | |
|---|---|---|
| μ | Δf = 2^{μ} · 15[kHz] | Cyclic prefix |
| 0 | 15 | Normal |
| 1 | 30 | Normal |
| 2 | 60 | Normal, |
| | | Extended |
| 3 | 120 | Normal |
| 4 | 240 | Normal |
| 5 | 480 | Normal |
| 6 | 960 | Normal |

For normal CP (14 symbols/slot), different numerologies μ 0 to 4 allow for 1, 2, 4, 8, and 16 slots, respectively, per subframe. For extended CP, the numerology 2 allows for 4 slots per subframe. Accordingly, for normal CP and numerology μ, there are 14 symbols/slot and 24 slots/subframe. The subcarrier spacing may be equal to 24*15 kHz, where u is the numerology 0 to 4. As such, the numerology μ=0 has a subcarrier spacing of 15 kHz and the numerology μ=4 has a subcarrier spacing of 240 kHz. The symbol length/duration is inversely related to the subcarrier spacing. FIGS. 2A-2D provide an example of normal CP with 14 symbols per slot and numerology μ=2 with 4 slots per subframe. The slot duration is 0.25 ms, the subcarrier spacing is 60 kHz, and the symbol duration is approximately 16.67 μs. Within a set of frames, there may be one or more different bandwidth parts (BWPs) (see FIG. 2B) that are frequency division multiplexed. Each BWP may have a particular numerology and CP (normal or extended).

A resource grid may be used to represent the frame structure. Each time slot includes a resource block (RB) (also referred to as physical RBs (PRBs)) that extends 12 consecutive subcarriers. The resource grid is divided into multiple resource elements (REs). The number of bits carried by each RE depends on the modulation scheme.

As illustrated in FIG. 2A, some of the REs carry reference (pilot) signals (RS) for the UE. The RS may include demodulation RS (DM-RS) (indicated as R for one particular configuration, but other DM-RS configurations are possible) and channel state information reference signals (CSI-RS) for channel estimation at the UE. The RS may also include beam measurement RS (BRS), beam refinement RS (BRRS), and phase tracking RS (PT-RS).

FIG. 2B illustrates an example of various DL channels within a subframe of a frame. The physical downlink control channel (PDCCH) carries DCI within one or more control channel elements (CCEs) (e.g., 1, 2, 4, 8, or 16 CCEs), each CCE including six RE groups (REGs), each REG including 12 consecutive REs in an OFDM symbol of an RB. A PDCCH within one BWP may be referred to as a control resource set (CORESET). A UE is configured to monitor PDCCH candidates in a PDCCH search space (e.g., common search space, UE-specific search space) during PDCCH monitoring occasions on the CORESET, where the PDCCH candidates have different DCI formats and different aggregation levels. Additional BWPs may be located at greater and/or lower frequencies across the channel bandwidth. A primary synchronization signal (PSS) may be within symbol 2 of particular subframes of a frame. The PSS is used by a UE 104 to determine subframe/symbol timing and a physical layer identity. A secondary synchronization signal (SSS) may be within symbol 4 of particular subframes of a frame. The SSS is used by a UE to determine a physical layer cell identity group number and radio frame timing. Based on the physical layer identity and the physical layer cell identity group number, the UE can determine a physical cell identifier (PCI). Based on the PCI, the UE can determine the locations of the DM-RS. The physical broadcast channel (PBCH), which carries a master information block (MIB), may be logically grouped with the PSS and SSS to form a synchronization signal (SS)/PBCH block (also referred to as SS block (SSB)). The MIB provides a number of RBs in the system bandwidth and a system frame number (SFN). The physical downlink shared channel (PDSCH) carries user data, broadcast system information not transmitted through the PBCH such as system information blocks (SIBs), and paging messages.

As illustrated in FIG. 2C, some of the REs carry DM-RS (indicated as R for one particular configuration, but other DM-RS configurations are possible) for channel estimation at the base station. The UE may transmit DM-RS for the physical uplink control channel (PUCCH) and DM-RS for the physical uplink shared channel (PUSCH). The PUSCH DM-RS may be transmitted in the first one or two symbols of the PUSCH. The PUCCH DM-RS may be transmitted in different configurations depending on whether short or long PUCCHs are transmitted and depending on the particular PUCCH format used. The UE may transmit sounding reference signals (SRS). The SRS may be transmitted in the last symbol of a subframe. The SRS may have a comb structure, and a UE may transmit SRS on one of the combs. The SRS may be used by a base station for channel quality estimation to enable frequency-dependent scheduling on the UL.

FIG. 2D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and hybrid automatic repeat request (HARQ) acknowledgment (ACK) (HARQ-ACK) feedback (i.e., one or more HARQ ACK bits indicating one or more ACK and/or negative ACK (NACK)). The PUSCH carries data, and may additionally be used to carry a buffer status report (BSR), a power headroom report (PHR), and/or UCI.

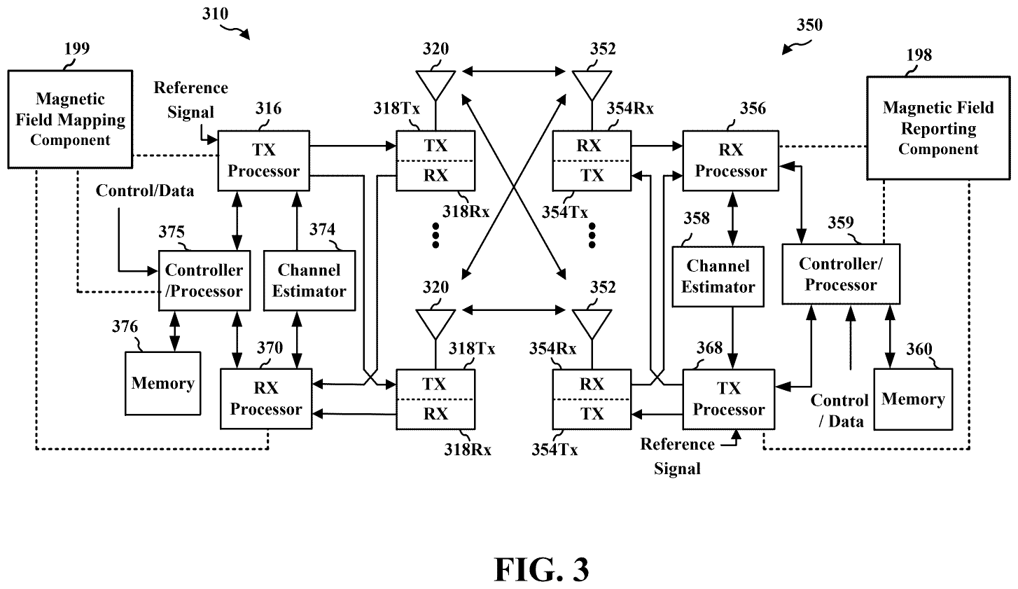

FIG. 3 is a block diagram of a base station 310 in communication with a UE 350 in an access network. In the DL, Internet protocol (IP) packets may be provided to a controller/processor 375. The controller/processor 375 implements layer 3 and layer 2 functionality. Layer 3 includes a radio resource control (RRC) layer, and layer 2 includes a service data adaptation protocol (SDAP) layer, a packet data convergence protocol (PDCP) layer, a radio link control (RLC) layer, and a medium access control (MAC) layer. The controller/processor 375 provides RRC layer functionality associated with broadcasting of system information (e.g., MIB, SIBs), RRC connection control (e.g., RRC connection paging, RRC connection establishment, RRC connection modification, and RRC connection release), inter radio access technology (RAT) mobility, and measurement configuration for UE measurement reporting; PDCP layer functionality associated with header compression/decompression, security (ciphering, deciphering, integrity protection, integrity verification), and handover support functions; RLC layer functionality associated with the transfer of upper layer packet data units (PDUs), error correction through ARQ, concatenation, segmentation, and reassembly of RLC service data units (SDUs), re-segmentation of RLC data PDUs, and reordering of RLC data PDUs; and MAC layer functionality associated with mapping between logical channels and transport channels, multiplexing of MAC SDUs onto transport blocks (TBs), demultiplexing of MAC SDUs from TBs, scheduling information reporting, error correction through HARQ, priority handling, and logical channel prioritization.

The transmit (TX) processor 316 and the receive (RX) processor 370 implement layer 1 functionality associated with various signal processing functions. Layer 1, which includes a physical (PHY) layer, may include error detection on the transport channels, forward error correction (FEC) coding/decoding of the transport channels, interleaving, rate matching, mapping onto physical channels, modulation/demodulation of physical channels, and MIMO antenna processing. The TX processor 316 handles mapping to signal constellations based on various modulation schemes (e.g., binary phase-shift keying (BPSK), quadrature phase-shift keying (QPSK), M-phase-shift keying (M-PSK), M-quadrature amplitude modulation (M-QAM)). The coded and modulated symbols may then be split into parallel streams. Each stream may then be mapped to an OFDM subcarrier, multiplexed with a reference signal (e.g., pilot) in the time and/or frequency domain, and then combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 374 may be used to determine the coding and modulation scheme, as well as for spatial processing. The channel estimate may be derived from a reference signal and/or channel condition feedback transmitted by the UE 350. Each spatial stream may then be provided to a different antenna 320 via a separate transmitter 318Tx. Each transmitter 318Tx may modulate a radio frequency (RF) carrier with a respective spatial stream for transmission.

At the UE 350, each receiver 354Rx receives a signal through its respective antenna 352. Each receiver 354Rx recovers information modulated onto an RF carrier and provides the information to the receive (RX) processor 356. The TX processor 368 and the RX processor 356 implement layer 1 functionality associated with various signal processing functions. The RX processor 356 may perform spatial processing on the information to recover any spatial streams destined for the UE 350. If multiple spatial streams are destined for the UE 350, they may be combined by the RX processor 356 into a single OFDM symbol stream. The RX processor 356 then converts the OFDM symbol stream from the time-domain to the frequency domain using a Fast Fourier Transform (FFT). The frequency domain signal includes a separate OFDM symbol stream for each subcarrier of the OFDM signal. The symbols on each subcarrier, and the reference signal, are recovered and demodulated by determining the most likely signal constellation points transmitted by the base station 310. These soft decisions may be based on channel estimates computed by the channel estimator 358. The soft decisions are then decoded and deinterleaved to recover the data and control signals that were originally transmitted by the base station 310 on the physical channel. The data and control signals are then provided to the controller/processor 359, which implements layer 3 and layer 2 functionality.

The controller/processor 359 can be associated with at least one memory 360 that stores program codes and data. The at least one memory 360 may be referred to as a computer-readable medium. In the UL, the controller/processor 359 provides demultiplexing between transport and logical channels, packet reassembly, deciphering, header decompression, and control signal processing to recover IP packets. The controller/processor 359 is also responsible for error detection using an ACK and/or NACK protocol to support HARQ operations.

Similar to the functionality described in connection with the DL transmission by the base station 310, the controller/processor 359 provides RRC layer functionality associated with system information (e.g., MIB, SIBs) acquisition, RRC connections, and measurement reporting; PDCP layer functionality associated with header compression/decompression, and security (ciphering, deciphering, integrity protection, integrity verification); RLC layer functionality associated with the transfer of upper layer PDUs, error correction through ARQ, concatenation, segmentation, and reassembly of RLC SDUs, re-segmentation of RLC data PDUs, and reordering of RLC data PDUs; and MAC layer functionality associated with mapping between logical channels and transport channels, multiplexing of MAC SDUs onto TBs, demultiplexing of MAC SDUs from TBs, scheduling information reporting, error correction through HARQ, priority handling, and logical channel prioritization.

Channel estimates derived by a channel estimator 358 from a reference signal or feedback transmitted by the base station 310 may be used by the TX processor 368 to select the appropriate coding and modulation schemes, and to facilitate spatial processing. The spatial streams generated by the TX processor 368 may be provided to different antennas 352 via separate transmitters 354Tx. Each transmitter 354Tx may modulate an RF carrier with a respective spatial stream for transmission.

The UL transmission is processed at the base station 310 in a manner similar to that described in connection with the receiver function at the UE 350. Each receiver 318Rx receives a signal through its respective antenna 320. Each receiver 318Rx recovers information modulated onto an RF carrier and provides the information to a RX processor 370.

The controller/processor 375 can be associated with at least one memory 376 that stores program codes and data. The at least one memory 376 may be referred to as a computer-readable medium. In the UL, the controller/processor 375 provides demultiplexing between transport and logical channels, packet reassembly, deciphering, header decompression, control signal processing to recover IP packets. The controller/processor 375 is also responsible for error detection using an ACK and/or NACK protocol to support HARQ operations.

At least one of the TX processor 368, the RX processor 356, and the controller/processor 359 may be configured to perform aspects in connection with the magnetic field reporting component 198 of FIG. 1.

At least one of the TX processor 316, the RX processor 370, and the controller/processor 375 may be configured to perform aspects in connection with the magnetic field mapping component 199 of FIG. 1.

A wireless device, in some aspects, may include an IMU used in determining a location and orientation of the device. A magnetometer, in some aspects, may be a component of the IMU and may provide the magnetic north (or south) direction. Combined with other measurements, the mobile device may estimate its orientation and or positioning using sensor fusion (e.g., Kalman filtering). Given a rough location estimation, a wireless device or UE may obtain an indication of a local magnetic field direction (e.g., a vector indicating a magnetic north or south) from a database and use the indicated direction for determining a location and/or orientation of the wireless device or UE.

In an open space, this usually works well. However, in a complex environment with many magnetic materials, the local magnetic field may be distorted and may not match the magnetic field direction indicated in the database. This will cause orientation and/or positioning errors. For example, a sensor fusion algorithm may not converge and may trigger a warning regarding an unreliability and/or a large uncertainty of an associated orientation and/or positioning determination. Therefore, a high resolution magnetic field database may provide for robust sensor fusion (e.g., for orientation estimation and/or positioning) in a complex environment (e.g., in an indoor office).

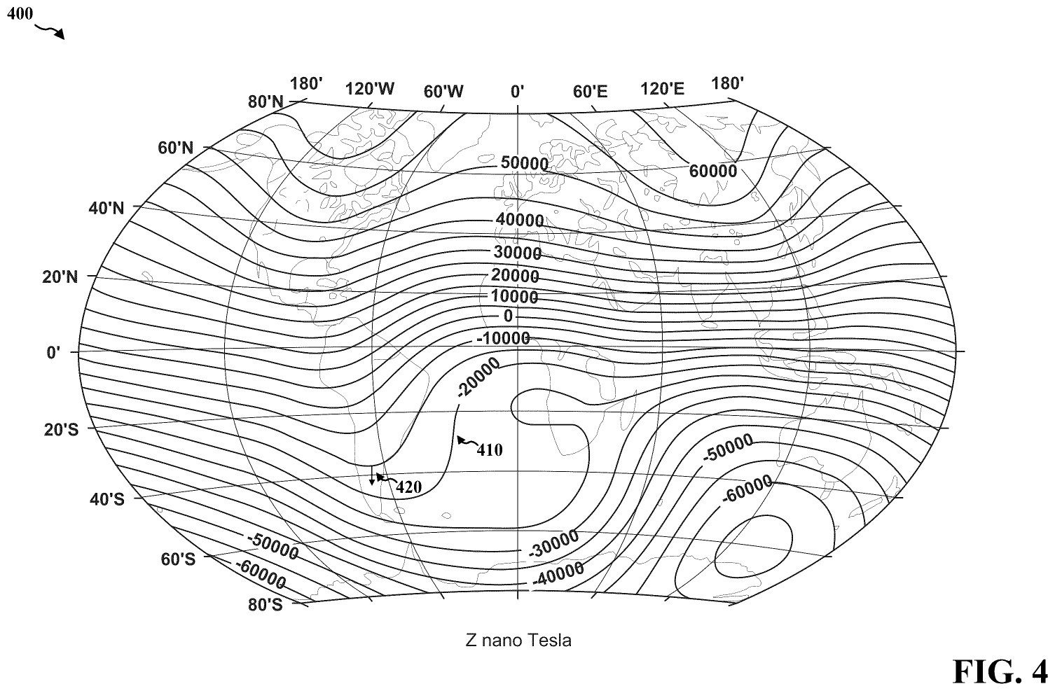

FIG. 4 is a diagram 400 illustrating large-scale fluctuations in magnetic field strength and direction that may be used in accordance with some aspects of the disclosure. Diagram 400 illustrates that the magnetic field strength varies over large distances. For example, contour line 410 represents locations having a same magnetic field strength (e.g., −20,000 nT) with other contour lines representing other magnetic field strengths (e.g., each line representing a 5000 nT change from an adjacent contour line). The information regarding magnetic field strength as a function of location may be stored by a network device and may be divided into regions of a useful size for particular applications (e.g., countries, states, counties, or cities) or geometric regions such as squares, rectangles, triangles, rhombuses, hexagons, or other shapes at different levels (e.g., having areas of 10,000 km², 1,000 km², 100 km², 10 km², 1 km², etc.). The information regarding the magnetic field may further include a magnetic field direction (e.g., may include a magnetic field vector indicating a magnitude and direction such as magnetic field vector 420). In some aspects, the magnetic field information may be used by a wireless device in one or more orientation and/or positioning operations to compare a locally-measured magnetic field to the expected magnetic field based on the magnetic field information.

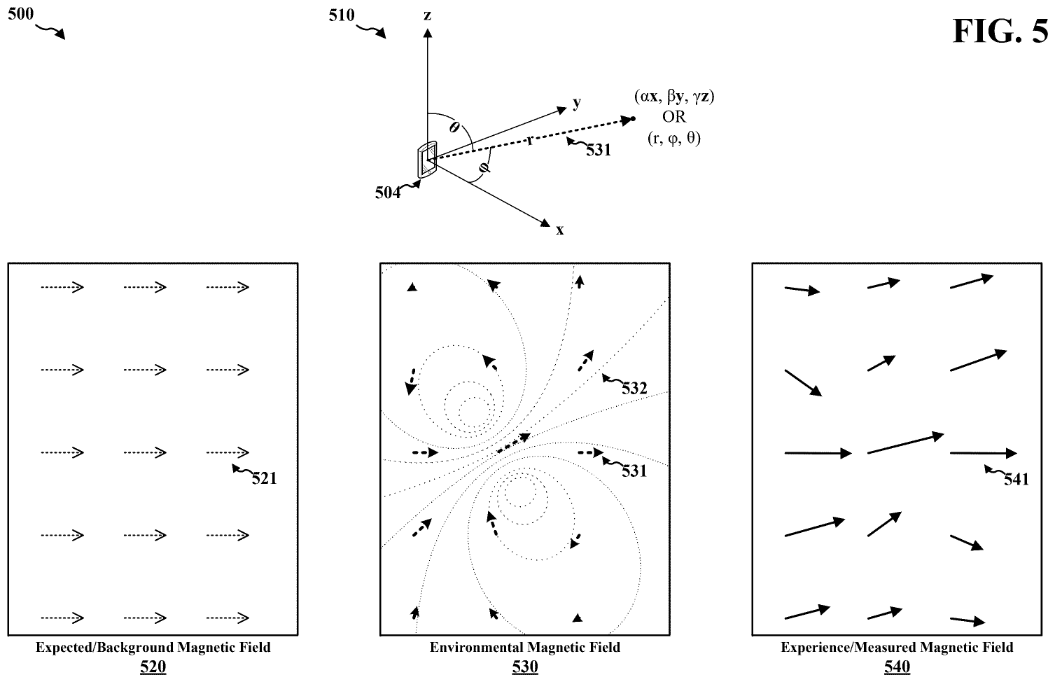

FIG. 5 is a diagram 500 illustrating a magnetic field measurement deviating from an expected magnetic field (e.g., from large scale magnetic field information) in the presence of a local magnetic field, in accordance with some aspects of the disclosure. Diagram 510 illustrates a UE 504 that may (e.g., via a magnetometer) measure a magnetic field to provide information for an orientation and/or positioning operation. The measurement may measure a field strength and a direction of the magnetic field to produce a vector including the magnitude and direction information. For example, Cartesian or polar coordinates may be used to represent the magnetic field with the axes defined relative to the UE 504 or by a set of axes defined based on some other reference (e.g., an objective or shared reference frame). Diagram 520 illustrates that within a first region a (near) constant magnetic field may be expected (e.g., the magnetic field vectors 521 indicating a direction and magnitude and shown as two-dimensional (2D) vectors for illustrative purposes). Diagram 530 illustrates that within the first region there may be additional magnetic fields (e.g., environmental magnetic fields from nearby electronic or power systems such as illustrated by contours 532) that may contribute to (e.g., magnetic field vectors 531 may be added to magnetic field vectors 521) a measured and/or experienced magnetic field as illustrated in diagram 540 (e.g., as indicated by vectors 541). Diagram 540 illustrates that, depending on the location within the first region, the UE 504 may measure a field that is different from the expected magnetic field by amounts that may be greater than, or less than, a threshold amount. The deviation may, in some aspects, be one or more of deviations from an expected magnitude of the magnetic field or deviations from an expected orientation (e.g., if orientation can be determined without the use of the magnetic field measurement).

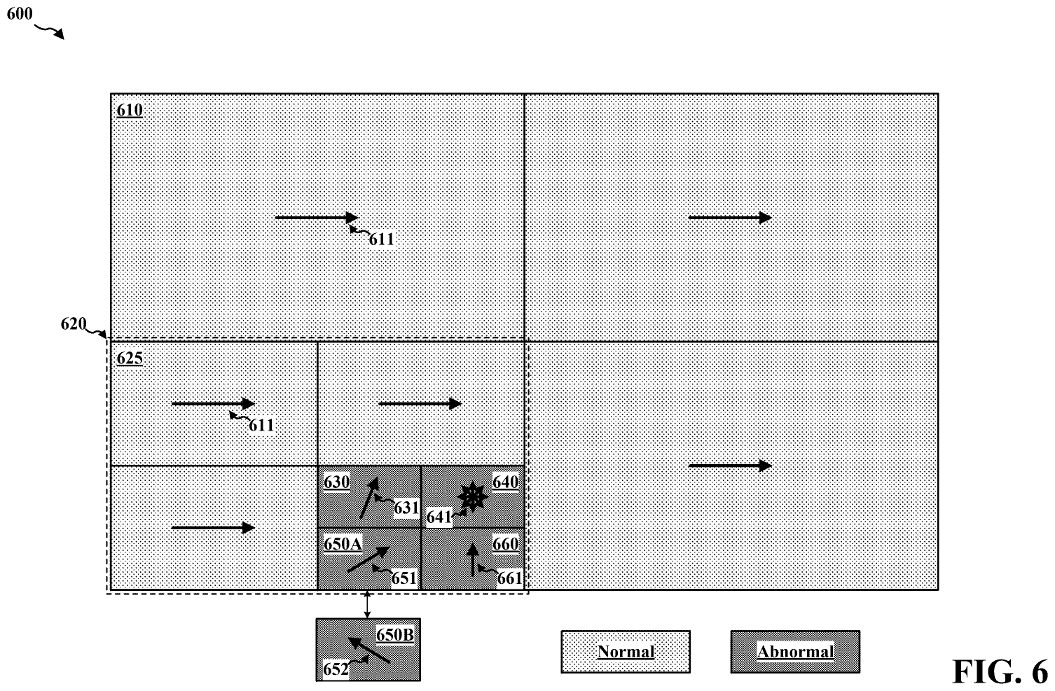

FIG. 6 is a diagram 600 illustrating a mapping of magnetic fields by region for regions defined at different levels of a hierarchy in accordance with some aspects of the disclosure. Diagram 600 illustrates a first region (e.g., a region encompassing an area over which magnetic fields are expected to be constant in the absence of “interference” from structures or electronic components) associated with a first magnetic field strength and direction (e.g., a magnetic field vector 611). The first region may be broken into four subregions (e.g., subregion 610) at a first level of a hierarchy. Each subregion for which the magnetic field is constant (or consistent with the large scale magnetic field), such as subregion 610, may remain undivided (e.g., may not be broken into additional subregions). Subregions for which the magnetic field is not consistent, such as subregion 620, may be further subdivided into a set of subregions at a second level of the hierarchy (e.g., a set of subregions included subregion 625). While a division into four equal subregions is illustrated, the division may be performed based on any known algorithm (e.g., a (dynamic) algorithm similar to ones used for identifying regions within images and/or videos for transmission over a network).

The subdivision for each non-constant (or non-consistent) region, in some aspects, may continue until an identified subregion at a particular level of hierarchy (e.g., subregion 630, subregion 650A, or subregion 660 at a third level of the hierarchy) is identified as having a constant magnetic field (e.g., represented by a magnetic field vector 631, a magnetic field vector 651, or a magnetic field vector 661). Alternatively, or additionally, in some aspects, the subdivision may continue until a subregion at a lowest level of the hierarchy (e.g., subregion 640 at the third level of the hierarchy in diagram 600) is identified as having, or being associated with, a non-constant (e.g., varying in time or space) magnetic field (e.g., magnetic field vector(s) 641). In some aspects, the first region may represent an outdoor area with a structure in one or more of subregion 630, 640, 650A, or 660, where indoor spaces may be more likely to be subject to magnetic field distortion. In some aspects, the magnetic field associated with each subregion (at each level of the hierarchy) may be associated with one or more of an indication of a deviation from the magnetic field vector 611 (e.g., a magnetic field difference vector 652 as indicated in association with subregion 650B corresponding to subregion 650A) or simply an indication that the subregion is normal and/or abnormal for the first region (e.g., via a single-bit in a bitmap or other data structure).

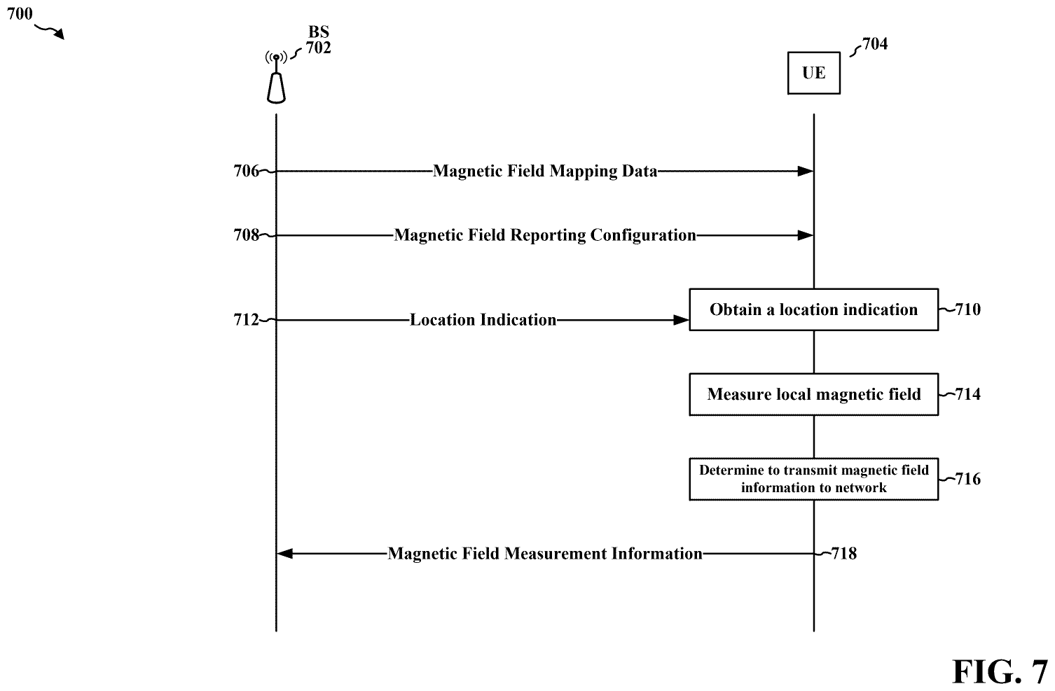

FIG. 7 is a call flow diagram 700 illustrating a method of wireless communication associated with reporting magnetic field information to a network in accordance with some aspects of the disclosure. Call flow diagram 700 includes a base station 702 (e.g., as an example of a network device or network node that may include one or more components of a disaggregated base station) that may be involved in communication with a UE 704 (e.g., as an example of a wireless device). The functions ascribed to the base station 702, in some aspects, may be performed by one or more components of a network such as an LMF, a network entity, a network node, or a network device (a single network entity/node/device or a disaggregated network entity/node/device as described above in relation to FIG. 1). Similarly, the functions ascribed to the UE 704, in some aspects, may be performed by one or more components of a wireless device supporting communication with a network entity/node/device. Accordingly, references to “transmitting” in the description below may be understood to refer to a first component of the base station 702 (or the UE 704) outputting (or providing) an indication of the content of the transmission to be transmitted by a different component of the base station 702 (or the UE 704). Similarly, references to “receiving” in the description below may be understood to refer to a first component of the base station 702 (or the UE 704) receiving a transmitted signal and outputting (or providing) the received signal (or information based on the received signal) to a different component of the base station 702 (or the UE 704).

The base station 702 may transmit, and a UE 704 may receive, a magnetic field mapping data 706. In some aspects, the magnetic field mapping information may be provided as assistance information. The magnetic field mapping data 706, in some aspects, may be related to a mapping at a first scale (e.g., at the scale of the first region of diagram 600). The magnetic field mapping data 706, in some aspects, may include one or more of a magnetic field strength and a magnetic field orientation (e.g., magnetic field vectors 521 or magnetic field vector 611).

In some aspects, the magnetic field mapping data 706 may additionally, or alternatively, include information regarding deviations from the magnetic field associated with the mapping at the first scale. The information regarding the deviations, in some aspects, may be a binary indication regarding whether each of a plurality of subregions is consistent or inconsistent with the mapping at the first scale. In some aspects, the information regarding the deviations may be an indication of one of a magnetic field strength and/or direction or of a magnitude and/or direction of a deviation from the magnetic field associated with the mapping at the first scale.

The base station 702, in some aspects, may transmit, and the UE 704 may receive, a magnetic field reporting configuration 708. The magnetic field reporting configuration 708, in some aspects, may indicate for the UE 704 to transmit magnetic field measurement information. The indication for the UE 704 to transmit magnetic field measurement information, in some aspects, may indicate time-based criteria (e.g., associated with a period defined in terms of slots, a SFN, or other unit of time or associated with a set of indicated times). In some aspects, the indication for the UE 704 to transmit magnetic field measurement information may indicate displacement-based criteria (e.g., associated with a displacement of 1 cm, 1 dm, 1 m, or other fixed distance in two or three dimensions). The indication for the UE 704 to transmit magnetic field measurement information, in some aspects, may indicate event-based criteria (e.g., based on detecting an abnormality, based on transitioning into (or out of) an abnormal region, based on receiving a request to provide magnetic field information). In some aspects, a request to provide magnetic field information may be associated with an indicated location and/or time at which to transmit the magnetic field information.

At 710, the UE 704 may obtain an indication of a location of the UE 704. In some aspects, obtaining the indication of the location of the wireless device may include one of determining the location of the wireless device, or receiving, from the base station 702, the location indication 712 indicating the location of the wireless device. The location indication 712 or the determination made at 710, in some aspects, may indicate a rough location estimation that may allow the UE 704 to determine an expected magnetic field at the UE 704.

At 714, the UE 704 may measure a magnetic field at the location of the UE 704. The magnetic field measurement at 714 may identify a magnetic field strength and direction of the magnetic field (e.g., relative to the UE 704 and or in a shared reference frame). In some aspects, the measured and/or identified magnetic field strength may be relative to large scale local magnetic field reference or may be identified using an absolute scale. The magnetic field measurement at 714 may further identify whether the magnetic field measurement is a maximum measurable magnetic field (e.g., whether the sensor has been saturated). The magnetic field measurement at 714 may identify an uncertainty associated with the magnetic field measurement.

Based on the magnetic field measurement at 714 and/or the magnetic field reporting configuration 708, the UE 704 may determine, at 716, to output (or transmit) magnetic field measurement information 718 (e.g., information regarding the location of the wireless device and the measured magnetic field at the location of the wireless device). As described in relation to the magnetic field reporting configuration 708, the determination may be based on a configured and/or indicated period, displacement, location, time, state, or transition. Alternatively, or additionally, the determination at 716 may be based on a difference between a magnetic field indicated in the magnetic field mapping data 706 and the magnetic field measured at 714. In some aspects, the UE 704 may determine at 716 to output (or transmit) the magnetic field measurement information 718 when the difference in the magnitude of the magnetic field is above a threshold value or if the difference in the orientation of the magnetic field is above a threshold value (if the orientation of the device can be determined with sufficient accuracy to identify the difference).

After determining at 716 to output (or transmit) the magnetic field measurement information 718, the UE 704 may transmit, and the base station 702 may receive magnetic field measurement information 718 (a set of information regarding one or more magnetic field measurements at the UE or wireless device). In some aspects, the magnetic field measurement information 718 may include at least one of first information regarding a strength and a direction of the magnetic field measured by the UE 704 at 714, second information regarding a sensor of the UE 704 used to measure the magnetic field at 714, third information regarding an orientation of the UE 704 while measuring the magnetic field at 714 (e.g., estimated using one or more of a Euler angle, a quaternion, a rotation matrix, or other method), and/or fourth information regarding a time associated with measuring the magnetic field at 714. The first information may be provided as a vector (e.g., in Cartesian or polar coordinates). The magnetic field measurement information 718 in some aspects, may be raw measurement data or calibrated measurement data. In some aspects, the magnetic field measurement information 718 may include an indication of whether the magnetic sensor has been saturated (e.g., whether the magnetic field is at least as strong as the strongest magnetic field measurable by the sensor).

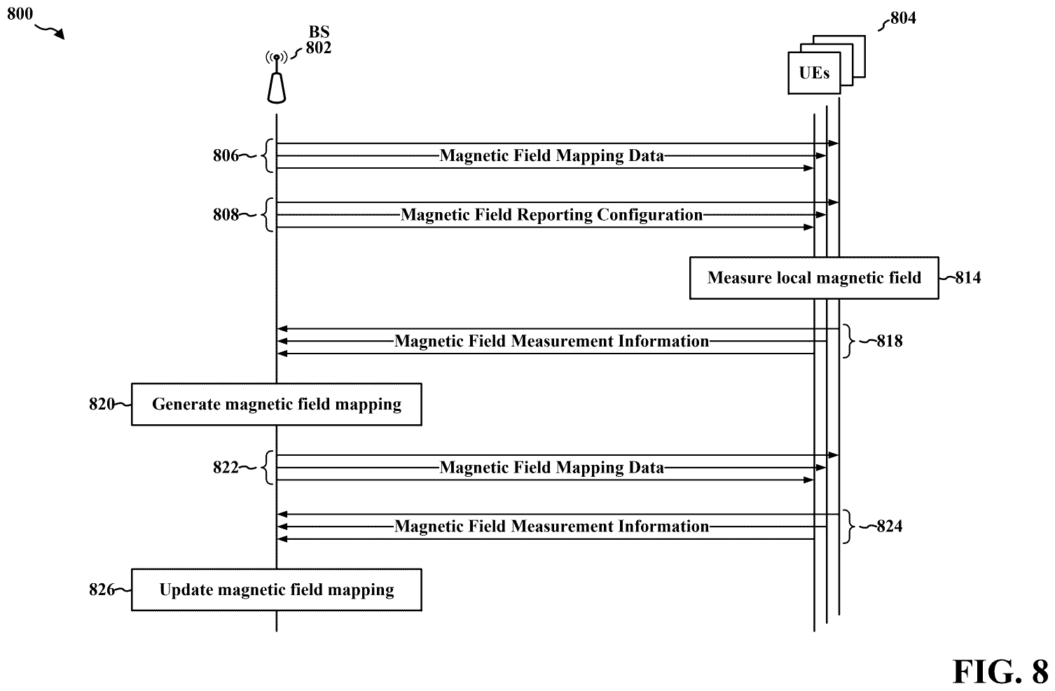

FIG. 8 is a call flow diagram 800 illustrating a method of wireless communication associated with using reported magnetic field information to generate a magnetic field mapping at a network in accordance with some aspects of the disclosure. Call flow diagram 800 includes a base station 802 (e.g., similar, or corresponding, to base station 702) that may be involved in communication with a plurality of UEs 804 (where each UE of the plurality of UEs 804 may be similar, or correspond, to UE 704). The functions ascribed to the base station 802, in some aspects, may be performed by one or more components of a network such as an LMF, a network entity, a network node, or a network device (a single network entity/node/device or a disaggregated network entity/node/device as described above in relation to FIG. 1). Similarly, the functions ascribed to the plurality of UEs 804, in some aspects, may be performed by one or more components of a wireless device supporting communication with a network entity/node/device. Accordingly, references to “transmitting” in the description below may be understood to refer to a first component of the base station 802 (or the plurality of UEs 804) outputting (or providing) an indication of the content of the transmission to be transmitted by a different component of the base station 802 (or the plurality of UEs 804). Similarly, references to “receiving” in the description below may be understood to refer to a first component of the base station 802 (or the plurality of UEs 804) receiving a transmitted signal and outputting (or providing) the received signal (or information based on the received signal) to a different component of the base station 802 (or the plurality of UEs 804).

The base station 802 may transmit, and the plurality of UEs 804 may receive, a magnetic field mapping data 806. In some aspects, the magnetic field mapping information may be provided as information in a particular format, or of a particular type (e.g., assistance information or assistance data provided by one network element to another network element or wireless device in association with one or more services or functions at the receiving device). The magnetic field mapping data 806, in some aspects, may be related to a mapping at a first scale (e.g., at the scale of the first region of diagram 600). The magnetic field mapping data 806, in some aspects, may include one or more of a magnetic field strength and a magnetic field orientation (e.g., magnetic field vectors 521 or magnetic field vectors 611). The magnetic field mapping data 806, in some aspects, may be specific to each UE of the plurality of UEs 804 based on a region. In some aspects, for example, if the plurality of UEs 804 are assumed to be served by a same base station 802, the magnetic field mapping data 806 may be the same information based on being in a same region.

In some aspects, the magnetic field mapping data 806 may additionally, or alternatively, include information regarding deviations from the magnetic field associated with the mapping at the first scale. The information regarding the deviations, in some aspects, may be a binary indication regarding whether each of a plurality of subregions is consistent or inconsistent with the mapping at the first scale. In some aspects, the information regarding the deviations may be an indication of one of a magnetic field strength and/or direction or of a magnitude and/or direction of a deviation from the magnetic field associated with the mapping at the first scale.

The base station 802, in some aspects, may transmit, and the plurality of UEs 804 may receive, a magnetic field reporting configuration 808. The magnetic field reporting configuration 808, in some aspects, may indicate for the plurality of UEs 804 to transmit magnetic field measurement information. The indication for the plurality of UEs 804 to transmit magnetic field measurement information, in some aspects, may indicate time-based criteria (e.g., associated with a period defined in terms of slots, a SFN, or other unit of time or associated with a set of indicated times). In some aspects, the indication for the plurality of UEs 804 to transmit magnetic field measurement information may indicate displacement-based criteria (e.g., associated with a displacement of 1 cm, 1 dm, 1 m, or other fixed distance in two or three dimensions). The indication for the plurality of UEs 804 to transmit magnetic field measurement information, in some aspects, may indicate event-based criteria (e.g., based on detecting an abnormality, based on transitioning into (or out of) an abnormal region, based on receiving a request to provide magnetic field information). In some aspects, a request to provide magnetic field information may be associated with an indicated location and/or time at which to transmit the magnetic field information.

As discussed in relation to FIG. 7, the plurality of UEs 804 may obtain an indication of a current location and determined to measure a magnetic field. At 814, each UE of the plurality of UEs 804 may measure a magnetic field at the location of the UE. The magnetic field measurement at 814 may identify a magnetic field strength and direction of the magnetic field (e.g., relative to the UE of the plurality of UEs 804 and or in a shared reference frame). The magnetic field measurement at 814 may further identify whether the magnetic field measurement is a maximum measurable magnetic field (e.g., whether the sensor has been saturated). The magnetic field measurement at 814 may identify an uncertainty associated with the magnetic field measurement.

Based on the magnetic field measurement at 814 and/or the magnetic field reporting configuration 808, the plurality of UEs 804 may determine to output (or transmit) magnetic field measurement information 818 (e.g., information regarding the location of the wireless device and the measured magnetic field at the location of the wireless device). As described in relation to the magnetic field reporting configuration 808, the determination may be based on a configured and/or indicated period, displacement, location, time, state, or transition. Alternatively, or additionally, the determination to output (or transmit) magnetic measurement information 818 may be based on a difference between a magnetic field indicated in the magnetic field mapping data 806 and the magnetic field measured at 814. In some aspects, the plurality of UEs 804 may determine to output (or transmit) the magnetic field measurement information 818 when the difference in the magnitude of the magnetic field is above a threshold value or if the difference in the orientation of the magnetic field is above a threshold value (if the orientation of the device can be determined with sufficient accuracy to identify the difference).

After determining to output (or transmit) the magnetic field measurement information 818, the plurality of UEs 804 may transmit, and the base station 802 may receive magnetic field measurement information 818 (one or more sets of information regarding one or more magnetic field measurements at one or more UEs or wireless devices). In some aspects, the magnetic field measurement information 818 may include at least one of first information regarding a strength and a direction of the magnetic field measured by each UE of the plurality of UEs 804 at 814, second information regarding a sensor of the UE of the plurality of UEs 804 used to measure the magnetic field at 814, third information regarding an orientation of the plurality of UEs 804 while measuring the magnetic field at 814 (e.g., estimated using one or more of a Euler angle, a quaternion, a rotation matrix, or other method), and/or fourth information regarding a time associated with measuring the magnetic field at 814. The first information may be provided as a vector (e.g., in Cartesian or polar coordinates). The magnetic field measurement information 818 in some aspects, may be raw measurement data or calibrated measurement data. In some aspects, the magnetic field measurement information 818 may include an indication of whether the magnetic sensor has been saturated (e.g., whether the magnetic field is at least as strong as the strongest magnetic field measurable by the sensor).

In some aspects, the magnetic field measurement information 818 may include magnetic field measurement information associated with different locations and/or different times. For example, a first UE of the plurality of UEs 804 may report a magnetic field measurement at a first location at a first time, a second UE of the plurality of UEs 804 may report a magnetic field measurement at the first location at a second time, and a third UE of the plurality of UEs 804 may report a magnetic field measurement at a second location at a third time.

Based on the plurality of magnetic field measurement information 818 (in addition to previously received magnetic field measurement information from the plurality of UEs 804 or other UEs not shown), the base station 802 may generate, at 820, a magnetic field mapping (e.g., a mapping of positions in space to magnetic field information). The magnetic field mapping generated at 820, in some aspects, may include at least one of a first mapping of magnetic field vectors to spatial positions (e.g., as depicted by magnetic field difference vector 652 or magnetic field vectors 611, 631, 651, or 661 of FIG. 6) or a second mapping identifying a first region associated with a magnetic field that is not consistent with a first known magnetic field for at least one second region including the first region (e.g., as depicted in diagram 600 in relation to subregions 630, 640, 650A, 650B, or 660 as opposed to subregions 610 and 625 within the first region). In some aspects, the first region may be identified as being indoors and the identification may be output or otherwise communicated to one or more other applications that may use that information to control aspects of the one or more other applications that may function differently when indoors (as compared to a function when outdoors).

The base station 802 may transmit, and the plurality of UEs 804 may receive, magnetic field mapping data 822. In some aspects, the magnetic field mapping data 822 may be different from the magnetic field mapping data 806. The difference, in some aspects, may be related to a format of the information. For example, the magnetic field mapping data 806 may include magnetic field magnitude and direction/orientation data for large-scale regions assuming uniformity across the region where the magnetic field mapping data 822 may include data regarding one of magnetic field strengths and directions (e.g., magnetic field vectors 631, 651, or 661), deviations from the large scale magnetic field strength and direction (e.g., magnetic field difference vector 652), or one or more abnormality indications for regions at different levels of a hierarchy within a region identified in a large scale region identified in the magnetic field mapping data 806.

In some aspects, the plurality of UEs 804 may transmit, and the base station 802 may receive, additional magnetic field measurement information 824. The additional magnetic field measurement information 824, in some aspects, may be similar to the magnetic field measurement information 818 (e.g., may include the same types of information). The base station 802, based on the magnetic field measurement information 824, may at 826 update the magnetic field mapping and provide the updated magnetic field mapping to the plurality of UEs 804 (not shown) as discussed in relation to magnetic field mapping data 822.

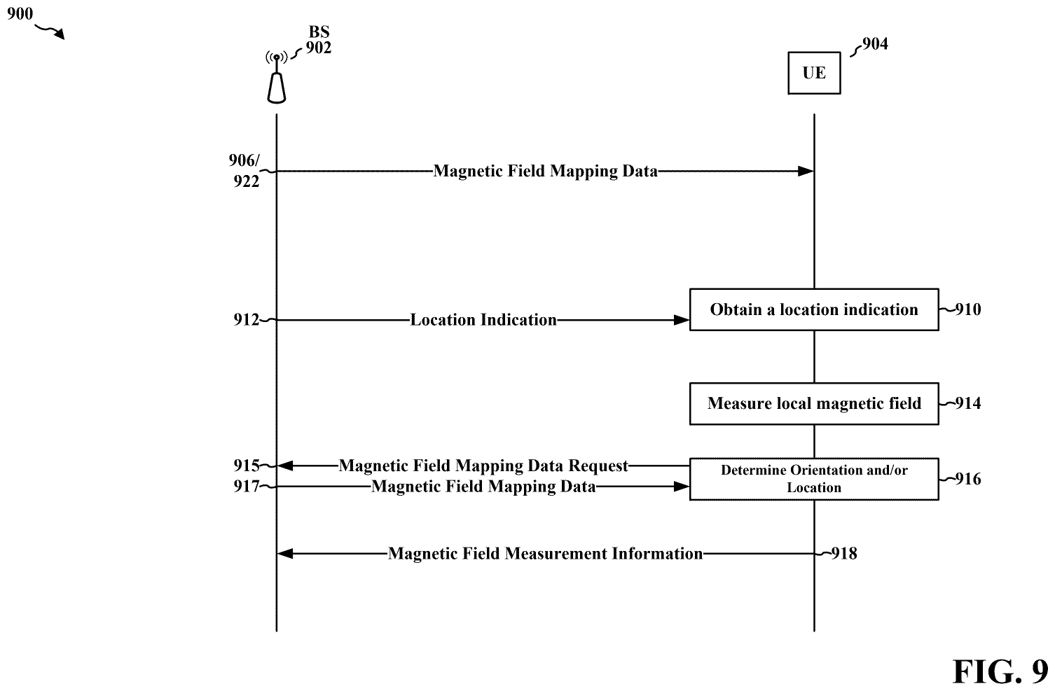

FIG. 9 is a call flow diagram 900 illustrating a method of wireless communication associated with using magnetic field information to determine a location in accordance with some aspects of the disclosure. Call flow diagram 900 includes a base station 902 (e.g., similar, or corresponding, to base station 702) that may be involved in communication with a UE 904 (where the UE 904 may be similar, or correspond, to UE 704). The functions ascribed to the base station 902, in some aspects, may be performed by one or more components of a network such as an LMF, a network entity, a network node, or a network device (a single network entity/node/device or a disaggregated network entity/node/device as described above in relation to FIG. 1). Similarly, the functions ascribed to the UE 904, in some aspects, may be performed by one or more components of a wireless device supporting communication with a network entity/node/device. Accordingly, references to “transmitting” in the description below may be understood to refer to a first component of the base station 902 (or the UE 904) outputting (or providing) an indication of the content of the transmission to be transmitted by a different component of the base station 902 (or the UE 904). Similarly, references to “receiving” in the description below may be understood to refer to a first component of the base station 902 (or the UE 904) receiving a transmitted signal and outputting (or providing) the received signal (or information based on the received signal) to a different component of the base station 902 (or the UE 904).

The base station 902 may transmit, and a UE 904 may receive, a magnetic field mapping data 906/922 (corresponding to one or both of magnetic field mapping data 806 and/or 822 of FIG. 8). In some aspects, the magnetic field mapping information may be provided as assistance information. The magnetic field mapping data 906/922, in some aspects, may be related to a mapping at a first scale (e.g., at the scale of the first region of diagram 600 or a subregion such as a subregion 630, 640, 650A, 650B, or 660). The magnetic field mapping data 906/922, in some aspects, may include one or more of a magnetic field strength and a magnetic field orientation (e.g., magnetic field vectors 521 or magnetic field vector 611).

In some aspects, the magnetic field mapping data 906/922 may additionally, or alternatively, include information regarding deviations from the magnetic field associated with the mapping at the first scale. The information regarding the deviations, in some aspects, may be a binary indication regarding whether each of a plurality of subregions is consistent or inconsistent with the mapping at the first scale. In some aspects, the information regarding the deviations may be an indication of one of a magnetic field strength and/or direction or of a magnitude and/or direction of a deviation from the magnetic field associated with the mapping at the first scale.

At 910, the UE 904 may obtain an indication of a location of the UE 904. In some aspects, obtaining the indication of the location of the wireless device may include one of determining the location of the wireless device, or receiving, from the base station 902, the location indication 912 indicating the location of the wireless device. The location indication 912 or the determination made at 910, in some aspects, may indicate a rough location estimation that may allow the UE 904 to determine an expected magnetic field at the UE 904.

At 914, the UE 904 may measure a magnetic field at the location of the UE 904. The magnetic field measurement at 914 may identify a magnetic field strength and direction of the magnetic field (e.g., relative to the UE 904 and or in a shared reference frame). The magnetic field measurement at 914 may further identify whether the magnetic field measurement is a maximum measurable magnetic field (e.g., whether the sensor has been saturated). The magnetic field measurement at 914 may identify an uncertainty associated with the magnetic field measurement.

Based on the magnetic field measurement at 914 and/or the magnetic field mapping data 906/922, the UE 904 may determine, at 916, an orientation and/or location of the UE 904. In some aspects, the determination at 916 may include one of omitting the measured magnetic field at the wireless device based on the mapping identifying the first region as an abnormal region or using the magnetic field at the wireless device and the magnetic field mapping data 906/922 to determine the orientation and/or location of the wireless based on a comparison between (or other function related to) the magnetic field indicated by the magnetic field mapping data 906/922 and the magnetic field measured at 914. For example, sensor fusion (e.g., Kalman filtering) may be applied based on the known magnetic field (e.g., the magnetic field indicated by the magnetic field mapping data 906/922), the magnetic field measured at 914, and GPS or other location information.

If the magnetic field mapping data 906/922 does not include information regarding a current (sub) region (e.g., information identifying the current (sub) region as being normal or abnormal, or consistent or inconsistent with large scale magnetic fields), the UE 904 may transmit, and the base station 902 may receive, a magnetic field mapping data request 915, to determine (1) if a current (sub) region is normal or abnormal or (2) a magnetic field associated with the current (sub) region (e.g., an indicated magnetic field strength and direction). Based on the magnetic field mapping data request 915, the base station 902 may transmit, and the UE 904 may receive, magnetic field mapping data 917 indicating one or more of (1) whether the current (sub) region is normal or abnormal (e.g., is consistent, or not consistent, with the magnetic field of a region including the (sub) region indicated in the magnetic field mapping data 906/922), (2) a deviation from a magnetic field indicated for a larger region including the current (sub) region, (3) a magnetic field strength and direction associated with the current (sub) region, or (4) whether the magnetic field strength and/or direction is unstable (and may be ignored or omitted from orientation and/or position determinations).

In some aspects, the determination at 916 may include trajectory-based location and/or orientation information. For example, the UE 904 may store or maintain data regarding magnetic field measurements taken at different times along with date regarding one or more of a location associated with each measurement or a displacement between subsequent measurements. The UE 904 may then determine, at 916, a most likely trajectory using a large scale mapping (e.g., in an extreme case the large scale mapping may be similar to the global magnetic field mapping data illustrated in FIG. 4). For example, knowing a magnetic field strength and orientation at a first time may enable the UE 904 to identify a first set of candidate and/or possible initial locations (on the globe or within a known region), while the displacement and/or location information associated with subsequent magnetic field measurements may allow the UE 904 to eliminate some of the candidate and/or possible initial locations based on the trajectory of the UE 904 and the known magnetic fields along the trajectory.

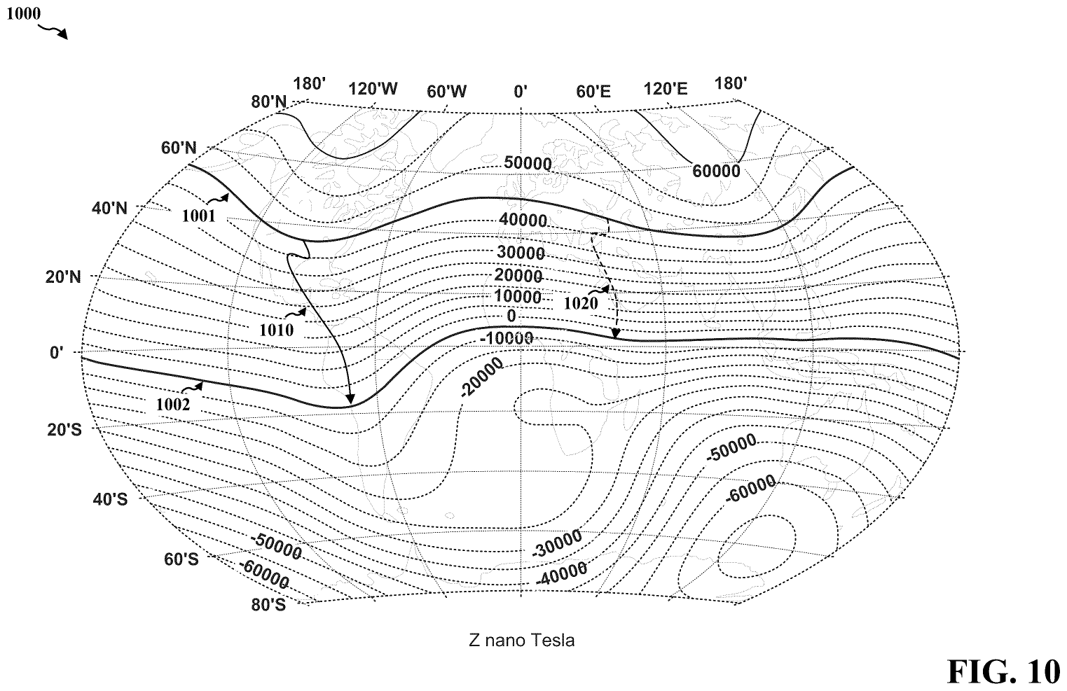

FIG. 10 is a diagram 1000 that illustrates two candidate trajectories between a first contour line associated with a first magnetic field strength and a second contour line having a second magnetic field strength in accordance with some aspects of the disclosure. For example, if an initial position is associated with a magnetic field strength of 45000 nT, the contour line 1001 may represent a set of candidate and/or possible initial locations. Similarly, if a current location is associated with a magnetic field strength of −5000 nT, the contour line 1002 may represent a set of candidate and/or possible current locations. The trajectory 1010 may represent an actual path of the UE (e.g., the UE 904) while the trajectory 1020 may represent a candidate and/or possible trajectory that may be eliminated based on the displacement and/or location information associated with subsequent magnetic field measurements. In some aspects, the trajectory-based determination at 916 may include (1) identifying multiple potential locations with a similar magnetic field, (2) using other available data (e.g., other sensors or RAN-dependent techniques) to narrow the list of multiple identified locations, (3) searching, based on additional measurements, the neighborhood of the previous and/or remaining potential locations to find the most likely direction to use as the heading direction, (4) comparing the likelihood of all the possible trajectories to prune out and/or eliminate the most unlikely one, and (5) repeating (3) and (4) until a single trajectory remains.

The location determination at 916, in some aspects, may be related to, or used in, determining to output magnetic field measurement information. For example, the location determined at 916 may be compared to location-based criteria for reporting magnetic field information indicated by a reporting configuration (as described in relation to magnetic field reporting configuration 708 and the determination to output (or transmit) the magnetic field measurement information at 716). Assuming that one or more reporting criteria has been met, the UE 904 may transmit, and the base station 902 may receive, magnetic field measurement information 918 based on the magnetic field measurement at 914 and, in some aspects, based on the orientation and location determination at 916. The magnetic field measurement information 918, in some aspects may include the same information as discussed formation

As described in relation to the magnetic field reporting configuration 708 and/or 808 of FIGS. 7 and/or 8, respectively, the determination may be based on a configured and/or indicated period, displacement, location, time, state, or transition. Alternatively, or additionally, the determination at 916 may be based on a difference between a magnetic field indicated in the magnetic field mapping data 906/922 and the magnetic field measured at 914. In some aspects, the UE 904 may determine at 916 to output (or transmit) the magnetic field measurement information 918 when the difference in the magnitude of the magnetic field is above a threshold value or if the difference in the orientation of the magnetic field is above a threshold value (if the orientation of the device can be determined with sufficient accuracy to identify the difference).

After determining at 916 to output (or transmit) the magnetic field measurement information 918, the UE 904 may transmit, and the base station 902 may receive magnetic field measurement information 918 (a set of information regarding one or more magnetic field measurements at the UE or wireless device). In some aspects, the magnetic field measurement information 918 may include at least one of first information regarding a strength and a direction of the magnetic field measured by the UE 904 at 914, second information regarding a sensor of the UE 904 used to measure the magnetic field at 914, third information regarding an orientation of the UE 904 while measuring the magnetic field at 914, and/or fourth information regarding a time associated with measuring the magnetic field at 914. The first information may be provided as a vector (e.g., in Cartesian or polar coordinates). The magnetic field measurement information 918 in some aspects, may be raw measurement data or calibrated measurement data. In some aspects, the magnetic field measurement information 918 may include an indication of whether the magnetic sensor has been saturated (e.g., whether the magnetic field is at least as strong as the strongest magnetic field measurable by the sensor).

In some aspects, the magnetic field measurement information 918 may include at least one of first information regarding a strength and a direction of the magnetic field measured by the UE 904 at 914, second information regarding a sensor of the UE 904 used to measure the magnetic field at 914, third information regarding an orientation of the UE 904 while measuring the magnetic field at 914 (e.g., estimated using one or more of a Euler angle, a quaternion, a rotation matrix, or other method), and/or fourth information regarding a time associated with measuring the magnetic field at 914. The first information may be provided as a vector (e.g., in Cartesian or polar coordinates). The magnetic field measurement information 918 in some aspects, may be raw measurement data or calibrated measurement data. In some aspects, the magnetic field measurement information 918 may include an indication of whether the magnetic sensor has been saturated (e.g., whether the magnetic field is at least as strong as the strongest magnetic field measurable by the sensor).

While FIGS. 7, 8, and 9, are separated for clarity, the operations (e.g., transmitting, receiving, and/or determining) described above for a base station (or a UE) may be performed by a same base station (or UE) at different times. In some aspects, similarly numbered operations may represent a single transmission or determination that is performed by a same device in association with multiple processes, purposes, and/or goals. Alternatively, or additionally, each operation may be performed as part of a repeated process for updating, maintaining, providing, and/or using magnetic field mapping information associated with the methods described in relation to FIGS. 7, 8, and 9 above. For example, each of the methods described in relation to FIGS. 7, 8, and 9, may overlap in time and the measurement of a local magnetic field at 714, 814, and 914, may be a same measurement operation associated with each of the reporting, map generation, and orientation/location determination functions and/or methods. In other words, the base station (or network function such as an LMF) may receive ongoing reports of magnetic fields from a plurality of UEs in an associated region, generate and/or update the magnetic field mapping information, and provide UEs with the current magnetic field information in an associated region or subregion. Similarly, each UE may be receiving magnetic field mapping information for a current region (with new information being provided as a UE transitions between regions and/or subregions), making multiple magnetic field measurements over time, using the magnetic field measurements and magnetic field information to determine an orientation and/or location, and/or reporting the magnetic field measurement information for at least a subset of the multiple magnetic field measurements.

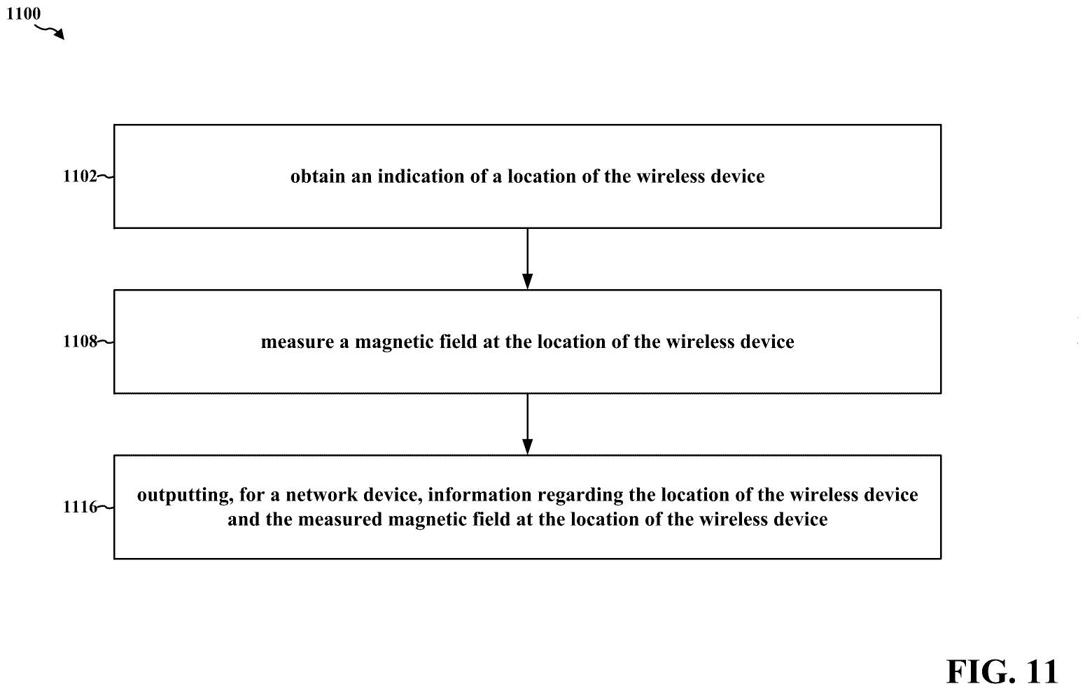

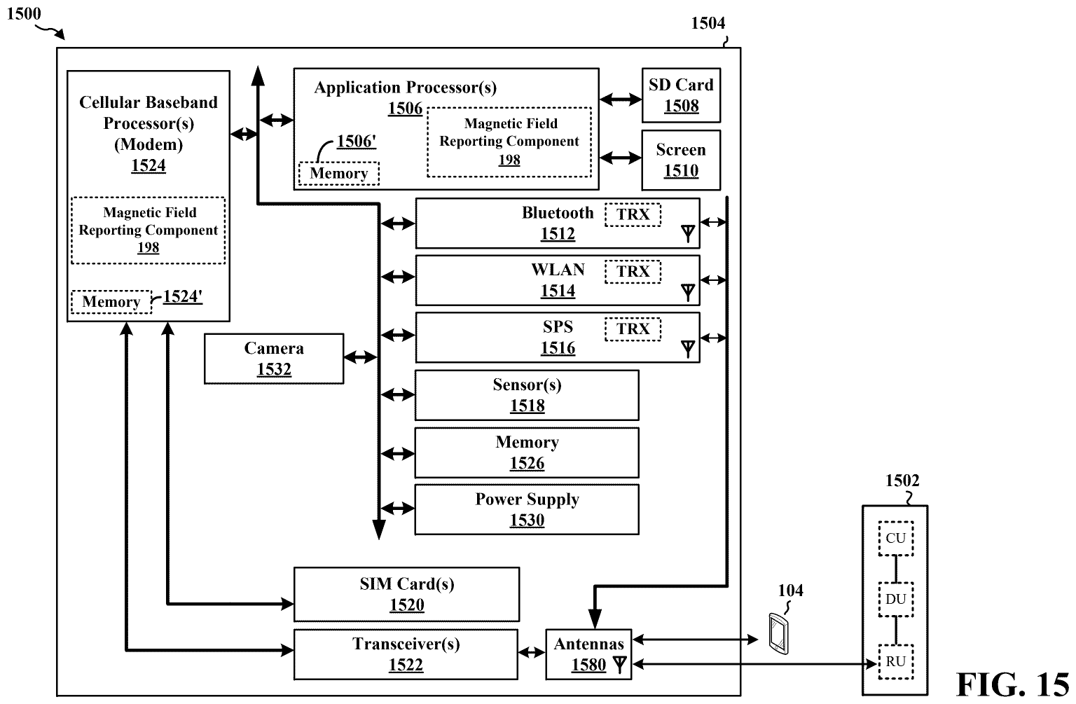

FIG. 11 is a flowchart 1100 of a method of wireless communication. The method may be performed by a wireless device such as a UE (e.g., the UE 104, 504 704, 904; the plurality of UEs 804; the apparatus 1504). At 1102, the wireless device may obtain an indication of a location of the wireless device. For example, 1102 may be performed by application processor(s) 1506, cellular baseband processor(s) 1524, transceiver(s) 1522, antenna(s) 1580, and/or magnetic field reporting component 198 of FIG. 15. In some aspects, obtaining the indication of the location of the wireless device may include at least one of determining the location of the wireless device (e.g., based on GPS or other positioning method) and/or receiving, from a network device, the indication of the location of the wireless device. For example, referring to FIGS. 7 and 9, the UE 704 (or 904) may obtain a location indication at 710 (or 910) that may be based on a location indication 712 (or 912) received from base station 702 (or 902).

In some aspects, the wireless device may receive, from the network device, an indication for the wireless device to provide information regarding a magnetic field measurement. The indication received, in some aspects, may include an indication of one or more triggering events or criteria for providing magnetic field measurement information to the network device. The indication for the wireless device to provide (or transmit) magnetic field measurement information, in some aspects, may indicate time-based criteria (e.g., associated with a period defined in terms of slots, a SFN, or other unit of time or associated with a set of indicated times). In some aspects, the indication for the wireless device to provide (or transmit) magnetic field measurement information may indicate displacement-based criteria (e.g., associated with a displacement of 1 cm, 1 dm, 1 m, or other fixed distance in two or three dimensions). The indication for the wireless device to provide (or transmit) magnetic field measurement information, in some aspects, may indicate event-based criteria (e.g., based on detecting an abnormality, based on transitioning into (or out of) an abnormal region, based on receiving a request to provide magnetic field information). In some aspects, a request to provide magnetic field information may be associated with an indicated location and/or time at which to transmit the magnetic field information. For example, referring to FIGS. 7 and 8, the UE 704 (or 804) may receive a magnetic field reporting configuration 708 (or 808).

At 1108, the wireless device may measure a magnetic field at the location of the wireless device. For example, 1108 may be performed by application processor(s) 1506, cellular baseband processor(s) 1524, and/or magnetic field reporting component 198 of FIG. 15. The magnetic field measurement at 1108 may identify a magnetic field strength and direction of the magnetic field (e.g., relative to the wireless device and or in a shared reference frame). The magnetic field measurement at 1108 may further identify whether the magnetic field measurement is a maximum measurable magnetic field (e.g., whether the sensor has been saturated). The magnetic field measurement at 1108 may identify an uncertainty associated with the magnetic field measurement. For example, referring to FIGS. 7, 8, and 9, the UE 704 (or 804 or 904) may measure a (local) magnetic field at 714, 814, or 914.

In some aspects, the wireless device may obtain a mapping of magnetic field information to a set of spatial positions. In some aspects, the mapping of magnetic field information to a set of spatial positions may include at least one of a first mapping of magnetic field vectors (or other indication of magnetic field strength and direction) to the set of spatial positions or a second mapping identifying a first region associated with at least one magnetic field that is not consistent with a first known magnetic field for at least one second region including the first region (e.g., identifying the first region as an abnormal region and/or subregion within a larger region). In some aspects, the magnetic field vectors may represent deviations from a previously identified magnetic field (associated with a region such as the second region including the first region). In some aspects, the mapping of magnetic field information may be received in response to a request from the wireless device (e.g., if the wireless device identifies that it does not have detailed magnetic field mapping information). For example, referring to FIGS. 7, 8, and 9, the UE 704 (or 804 or 904) may receive a magnetic field mapping data 706, 822, 906/922, or 917 magnetic field reporting configuration 708 (or 808).

In some aspects, the wireless device may determine a position of the wireless device using the mapping of the magnetic field information to the set of spatial positions. In some aspects, determining the location may include one or more of omitting the measured magnetic field at the wireless device based on the mapping identifying the first region (as being abnormal), using the magnetic field at the wireless device and the mapping, and/or using the mapping and a plurality of measurements of the magnetic field at the wireless device associated with a corresponding plurality of times to determine a current position. Referring to FIG. 9, for example, the UE 904 may, at 916, determine an orientation and/or location of the UE 904 based on the magnetic field measured at 914 and/or magnetic field mapping data 906/922 and/or magnetic field mapping data 917.

At 1116, the wireless device may output, for the network device, information regarding the location of the wireless device and the measured magnetic field at the location of the wireless device. In some aspects, the wireless device may determine to output the information based on detecting an indicated triggering event and may transmit the information regarding the location of the wireless device and the measured magnetic field at the location of the wireless device to the network device. For example, 1116 may be performed by application processor(s) 1506, cellular baseband processor(s) 1524, transceiver(s) 1522, antenna(s) 1580, and/or magnetic field reporting component 198 of FIG. 15. In some aspects, determining to output the information may be based on satisfying one or more criteria indicated in the indication for the wireless device to provide information regarding a magnetic field measurement. For example, the wireless device may determine to output the information based on at least one of detecting an anomaly in the magnetic field at the wireless device, a configured periodicity, or a request to output the information. In some aspects, detecting an anomaly may include detecting at least one of a first difference between the measured magnetic field and a first known magnetic field with a first magnitude larger than a first threshold value, a second difference between a first orientation of the wireless device based on at least one other sensor and a second orientation of the wireless device based on the first known magnetic field with a second magnitude that is larger than a second threshold value, or a third difference between a first magnetic field direction associated with the first known magnetic field and a second magnetic field direction measured at the wireless device (e.g., based on an orientation of the wireless device based on other sensors of the device or other positioning and orientation information) that is greater than a third threshold value. For example, referring to FIGS. 7, 8, and 9, the UE 704 (or 804 or 904) may determine, at 716, to output (or transmit) magnetic field measurement information 718 (e.g., information regarding the location of the wireless device and the measured magnetic field at the location of the wireless device).

The information regarding the location of the wireless device and the measured magnetic field at the location of the wireless device, in some aspects, may include at least one of first information regarding a strength and a direction of the magnetic field measured by the wireless device at 1108, second information regarding a sensor of the wireless device used to measure the magnetic field at 1108, third information regarding an orientation of the wireless device while measuring the magnetic field at 1108 (e.g., estimated using one or more of a Euler angle, a quaternion, a rotation matrix, or other method), and/or fourth information regarding a time associated with measuring the magnetic field at 1108. The first information may be provided as a vector (e.g., in Cartesian or polar coordinates). The information regarding the location of the wireless device and the measured magnetic field at the location of the wireless device, in some aspects, may be raw measurement data or calibrated measurement data. In some aspects, the information regarding the location of the wireless device and the measured magnetic field at the location of the wireless device may include an indication of whether the magnetic sensor has been saturated (e.g., whether the magnetic field is at least as strong as the strongest magnetic field measurable by the sensor). For example, referring to FIGS. 7, 8, and 9, the UE 704 (or 804 or 904) may transmit, and the base station 702 (or 802 or 902) may receive, magnetic field measurement information 718 (or 818, 824, or 918) (e.g., information regarding the location of the wireless device and the measured magnetic field at the location of the wireless device).

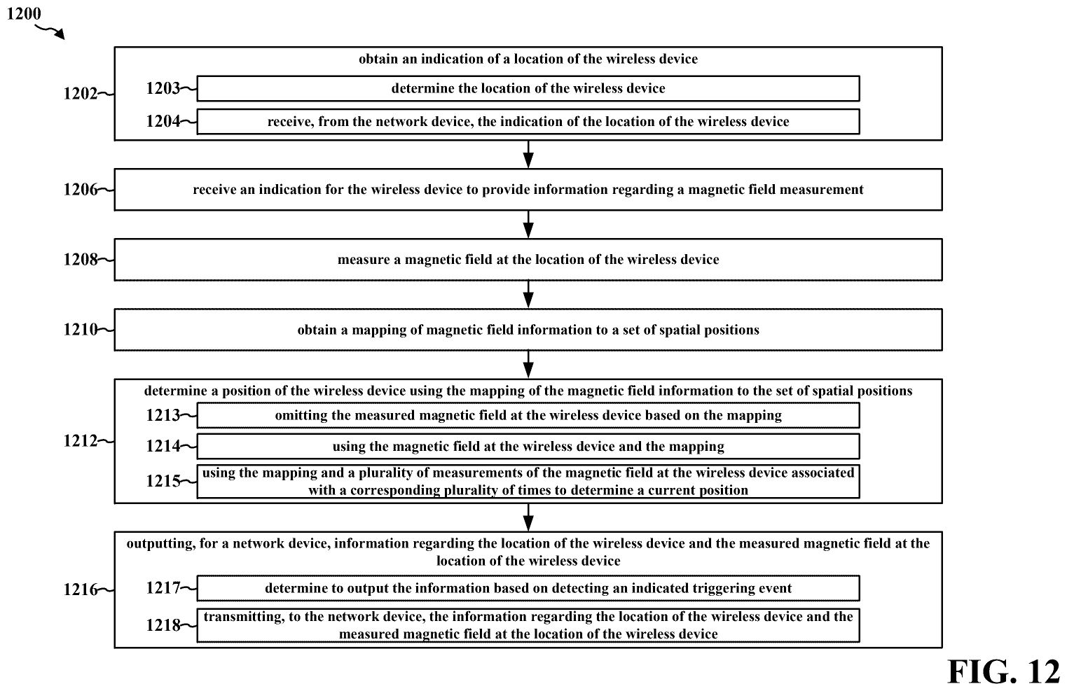

FIG. 12 is a flowchart 1200 of a method of wireless communication. The method may be performed by a wireless device such as a UE (e.g., the UE 104, 504 704, 904; the plurality of UEs 804; the apparatus 1504). At 1202, the wireless device may obtain an indication of a location of the wireless device. For example, 1202 may be performed by application processor(s) 1506, cellular baseband processor(s) 1524, transceiver(s) 1522, antenna(s) 1580, and/or magnetic field reporting component 198 of FIG. 15. In some aspects, obtaining the indication of the location of the wireless device may include at least one of determining the location of the wireless device (e.g., based on GPS or other positioning method) at 1203 and/or receiving, from a network device, the indication of the location of the wireless device at 1204. For example, referring to FIGS. 7 and 9, the UE 704 (or 904) may obtain a location indication at 710 (or 910) that may be based on a location indication 712 (or 912) received from base station 702 (or 902).

At 1206, the wireless device may receive, from the network device, an indication for the wireless device to provide information regarding a magnetic field measurement. For example, 1206 may be performed by application processor(s) 1506, cellular baseband processor(s) 1524, transceiver(s) 1522, antenna(s) 1580, and/or magnetic field reporting component 198 of FIG. 15. The indication received at 1204, in some aspects, may include an indication of one or more triggering events or criteria for providing magnetic field measurement information to the network device. The indication for the wireless device to provide (or transmit) magnetic field measurement information, in some aspects, may indicate time-based criteria (e.g., associated with a period defined in terms of slots, a SFN, or other unit of time or associated with a set of indicated times). In some aspects, the indication for the wireless device to provide (or transmit) magnetic field measurement information may indicate displacement-based criteria (e.g., associated with a displacement of 1 cm, 1 dm, 1 m, or other fixed distance in two or three dimensions). The indication for the wireless device to provide (or transmit) magnetic field measurement information, in some aspects, may indicate event-based criteria (e.g., based on detecting an abnormality, based on transitioning into (or out of) an abnormal region, based on receiving a request to provide magnetic field information). In some aspects, a request to provide magnetic field information may be associated with an indicated location and/or time at which to transmit the magnetic field information. For example, referring to FIGS. 7 and 8, the UE 704 (or 804) may receive a magnetic field reporting configuration 708 (or 808).

At 1208, the wireless device may measure a magnetic field at the location of the wireless device. For example, 1208 may be performed by application processor(s) 1506, cellular baseband processor(s) 1524, and/or magnetic field reporting component 198 of FIG. 15. The magnetic field measurement at 1208 may identify a magnetic field strength and direction of the magnetic field (e.g., relative to the wireless device and or in a shared reference frame). The magnetic field measurement at 1208 may further identify whether the magnetic field measurement is a maximum measurable magnetic field (e.g., whether the sensor has been saturated). The magnetic field measurement at 1208 may identify an uncertainty associated with the magnetic field measurement. For example, referring to FIGS. 7, 8, and 9, the UE 704 (or 804 or 904) may measure a (local) magnetic field at 714, 814, or 914.

At 1210, the wireless device may obtain a mapping of magnetic field information to a set of spatial positions. For example, 1210 may be performed by application processor(s) 1506, cellular baseband processor(s) 1524, transceiver(s) 1522, antenna(s) 1580, and/or magnetic field reporting component 198 of FIG. 15. In some aspects, the mapping of magnetic field information to a set of spatial positions may include at least one of a first mapping of magnetic field vectors (or other indication of magnetic field strength and direction) to the set of spatial positions or a second mapping identifying a first region associated with at least one magnetic field that is not consistent with a first known magnetic field for at least one second region including the first region (e.g., identifying the first region as an abnormal region and/or subregion within a larger region). In some aspects, the magnetic field vectors may represent deviations from a previously identified magnetic field (associated with a region such as the second region including the first region). In some aspects, the mapping of magnetic field information may be received in response to a request from the wireless device (e.g., if the wireless device identifies that it does not have detailed magnetic field mapping information). For example, referring to FIGS. 7, 8, and 9, the UE 704 (or 804 or 904) may receive a magnetic field mapping data 706, 822, 906/922, or 917 magnetic field reporting configuration 708 (or 808).

At 1212, the wireless device may determine a position of the wireless device using the mapping of the magnetic field information to the set of spatial positions. In some aspects, determining the location may include one or more of omitting, at 1213, the measured magnetic field at the wireless device based on the mapping identifying the first region (as being abnormal), using, at 1214, the magnetic field at the wireless device and the mapping, and/or using, at 1215, the mapping and a plurality of measurements of the magnetic field at the wireless device associated with a corresponding plurality of times to determine a current position. For example, 1212, 1213, 1214, and/or 1215 may be performed by application processor(s) 1506, cellular baseband processor(s) 1524, transceiver(s) 1522, antenna(s) 1580, and/or magnetic field reporting component 198 of FIG. 15. Referring to FIG. 9, for example, the UE 904 may, at 916, determine an orientation and/or location of the UE 904 based on the magnetic field measured at 914 and/or magnetic field mapping data 906/922 and/or magnetic field mapping data 917.

At 1216, the wireless device may output, for the network device, information regarding the location of the wireless device and the measured magnetic field at the location of the wireless device. In some aspects, the wireless device may, at 1217, determine to output the information based on detecting an indicated triggering event and may, at 1218, transmit the information regarding the location of the wireless device and the measured magnetic field at the location of the wireless device to the network device. For example, 1216, 1217, and/or 1218 may be performed by application processor(s) 1506, cellular baseband processor(s) 1524, transceiver(s) 1522, antenna(s) 1580, and/or magnetic field reporting component 198 of FIG. 15. In some aspects, determining to output the information may be based on satisfying one or more criteria indicated in the indication for the wireless device to provide information regarding a magnetic field measurement received at 1206. For example, the wireless device may determine to output the information based on at least one of detecting an anomaly in the magnetic field at the wireless device, a configured periodicity, or a request to output the information. In some aspects, detecting an anomaly may include detecting at least one of a first difference between the measured magnetic field and a first known magnetic field with a first magnitude larger than a first threshold value or a second difference between a first orientation based on at least one other sensor and a second orientation based on the first known magnetic field with a second magnitude that is larger than a second threshold value. For example, referring to FIGS. 7, 8, and 9, the UE 704 (or 804 or 904) may determine, at 716, to output (or transmit) magnetic field measurement information 718 (e.g., information regarding the location of the wireless device and the measured magnetic field at the location of the wireless device).

The information regarding the location of the wireless device and the measured magnetic field at the location of the wireless device, in some aspects, may include at least one of first information regarding a strength and a direction of the magnetic field measured by the wireless device at 1208, second information regarding a sensor of the wireless device used to measure the magnetic field at 1208, third information regarding an orientation of the wireless device while measuring the magnetic field at 1208 (e.g., estimated using one or more of a Euler angle, a quaternion, a rotation matrix, or other method), and/or fourth information regarding a time associated with measuring the magnetic field at 1208. The first information may be provided as a vector (e.g., in Cartesian or polar coordinates). The information regarding the location of the wireless device and the measured magnetic field at the location of the wireless device, in some aspects, may be raw magnetic field measurement data (e.g., an output from a sensor of the wireless device without correction and/or compensation) or calibrated magnetic field measurement data. In some aspects, the information regarding the location of the wireless device and the measured magnetic field at the location of the wireless device may include an indication of whether the magnetic sensor has been saturated (e.g., whether the magnetic field is at least as strong as the strongest magnetic field measurable by the sensor). For example, referring to FIGS. 7, 8, and 9, the UE 704 (or 804 or 904) may transmit, and the base station 702 (or 802 or 902) may receive, magnetic field measurement information 718 (or 818, 824, or 918) (e.g., information regarding the location of the wireless device and the measured magnetic field at the location of the wireless device).

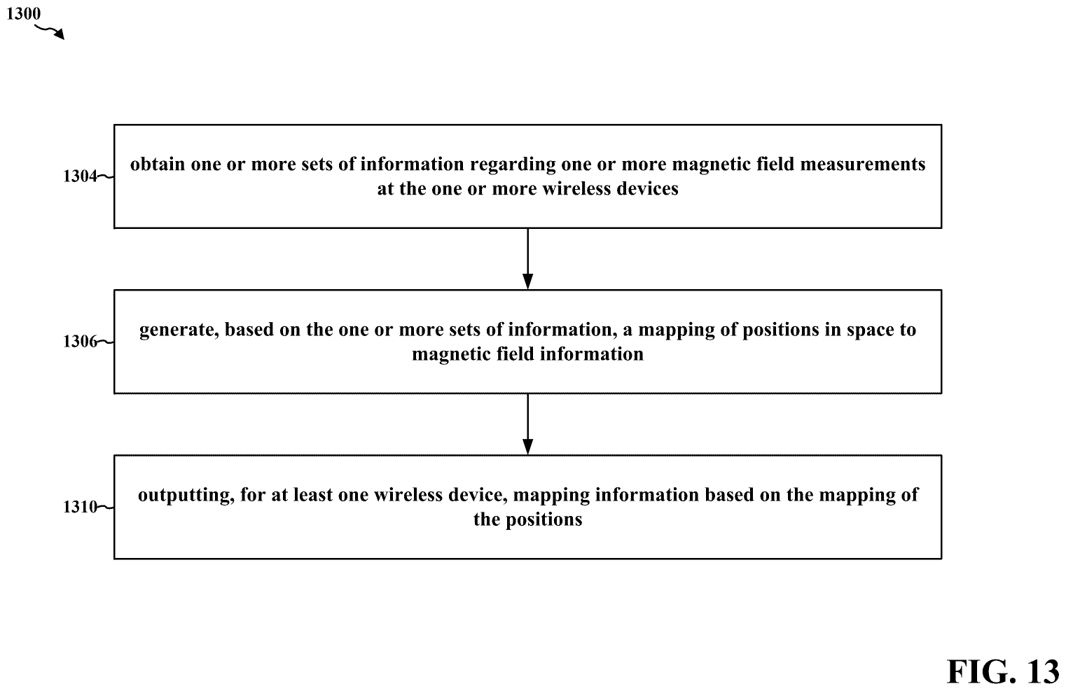

FIG. 13 is a flowchart 1300 of a method of wireless communication. The method may be performed by a network device such as a network node or a base station (e.g., the base station 102, 702, 802, 902; the network entity 1502, 1602, 1760). In some aspects, the network node may output an indication for a first wireless device of one or more wireless devices to provide information regarding a magnetic field measurement at the first wireless device. The indication, in some aspects, may include an indication of one or more triggering events or criteria for providing magnetic field measurement information to the network device. The indication for the first wireless device to provide (or transmit) magnetic field measurement information, in some aspects, may indicate time-based criteria (e.g., associated with a period defined in terms of slots, a SFN, or other unit of time or associated with a set of indicated times). In some aspects, the indication for the first wireless device to provide (or transmit) magnetic field measurement information may indicate displacement-based criteria (e.g., associated with a displacement of 1 cm, 1 dm, 1 m, or other fixed distance in two or three dimensions). The indication for the first wireless device to provide (or transmit) magnetic field measurement information, in some aspects, may indicate event-based criteria (e.g., based on detecting an abnormality, based on transitioning into (or out of) an abnormal region, based on receiving a request to provide magnetic field information). In some aspects, an indication (or request) to provide magnetic field information may be associated with an indicated location and/or time at which to transmit the magnetic field information. For example, referring to FIGS. 7 and 8, the base station 702 (or 802) may transmit a magnetic field reporting configuration 708 (or 808).

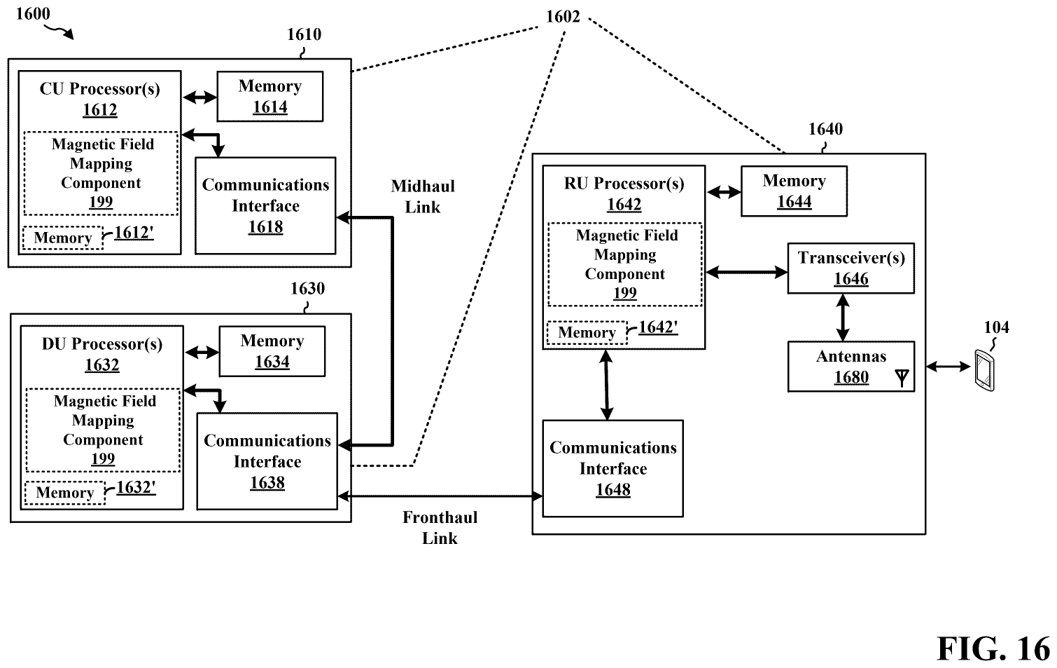

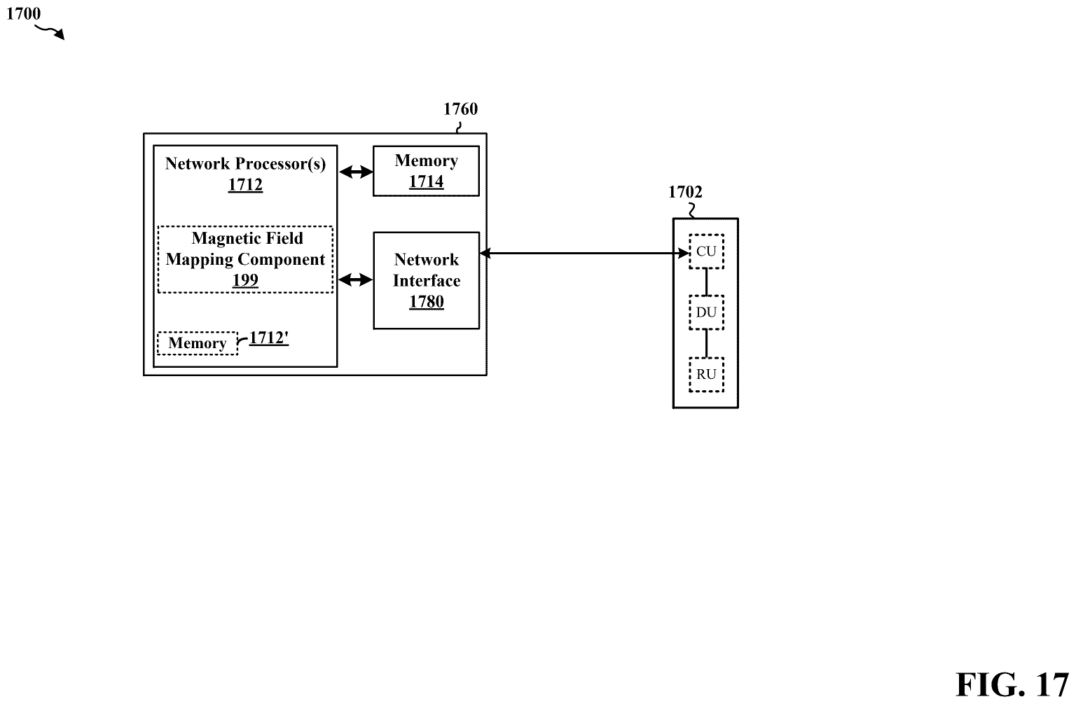

At 1304, the network device may obtain one or more sets of information regarding one or more magnetic field measurements at one or more wireless devices. For example, 1304 may be performed by CU processor(s) 1612, DU processor(s) 1632, RU processor(s) 1642, transceiver(s) 1646, antenna(s) 1680, network processor 1712, network interface 1780, and/or magnetic field mapping component 199 of FIGS. 16 and 17. A set of information in the one or more sets of information regarding one or more magnetic field measurements at the one or more wireless devices (e.g., regarding the location of the wireless device and the measured magnetic field at the location of the wireless device), in some aspects, may include at least one of first information regarding a strength and a direction of the magnetic field measured by a wireless device, second information regarding a sensor of the wireless device used to measure the magnetic field, third information regarding an orientation of the wireless device while measuring the magnetic field, and/or fourth information regarding a time associated with measuring the magnetic field. The first information may be provided as a vector (e.g., in Cartesian or polar coordinates). The information regarding one or more magnetic field measurements at one or more wireless devices (e.g., information regarding the location of the wireless device and the measured magnetic field at the location of the wireless device), in some aspects, may be raw measurement data or calibrated measurement data. In some aspects, the information regarding the location of the wireless device and the measured magnetic field at the location of the wireless device may include an indication of whether the magnetic sensor has been saturated (e.g., whether the magnetic field is at least as strong as the strongest magnetic field measurable by the sensor). For example, referring to FIGS. 7, 8, and 9, the base station 702 (or 802 or 902) may receive, magnetic field measurement information 718 (or 818, 824, or 918) (e.g., information regarding the location of the wireless device and the measured magnetic field at the location of the wireless device) from the plurality of UEs 804.

At 1306, the network device may generate, based on the one or more sets of information, a mapping of positions in space to magnetic field information. For example, 1306 may be performed by CU processor(s) 1612, DU processor(s) 1632, RU processor(s) 1642, transceiver(s) 1646, antenna(s) 1680, network processor 1712, network interface 1780, and/or magnetic field mapping component 199 of FIGS. 16 and 17. The magnetic field mapping generated at 1306, in some aspects, may include at least one of a first mapping of magnetic field vectors to spatial positions (e.g., as depicted by magnetic field difference vector 652 or magnetic field vectors 611, 631, 651, or 661 of FIG. 6) or a second mapping identifying a first region associated with a magnetic field that is not consistent with a first known magnetic field for at least one second region including the first region (e.g., as depicted in diagram 600 in relation to subregions 630, 640, 650A, 650B, or 660 as opposed to subregions 610 and 625 within the first region). In some aspects, the identification of the first region may further indicate that the first region is an indoor region such that other applications may be alerted to adjust one or more parameters or operations for indoor function. For example, referring to FIG. 8, the base station 802 may, at 820 magnetic field mapping (e.g., a mapping of positions in space to magnetic field information). In some aspects, the network device may receive, from a first wireless device, a request for the mapping information for a region associated with the first wireless device. Referring to FIG. 9, for example, the base station 902 may receive a magnetic field mapping data request 915.

At 1310, the network device may output, for at least one wireless device (e.g., the first wireless device), mapping information based on the mapping of the positions in space to magnetic field information. In some aspects, outputting the mapping information may include transmitting, based on the request received at 1308, the mapping information based on the mapping of the positions in space to magnetic field information. For example, 1310 may be performed by CU processor(s) 1612, DU processor(s) 1632, RU processor(s) 1642, transceiver(s) 1646, antenna(s) 1680, network processor 1712, network interface 1780, and/or magnetic field mapping component 199 of FIGS. 16 and 17. In some aspects, the network may determine to output the mapping of the positions in space to magnetic field information to the first wireless device in response to identifying that the first wireless device has transitioned between regions and/or that a current region associated with the first wireless device has an updated status (switching from normal to abnormal or vice versa). The mapping information, in some aspects, may be the mapping information generated at 1306.

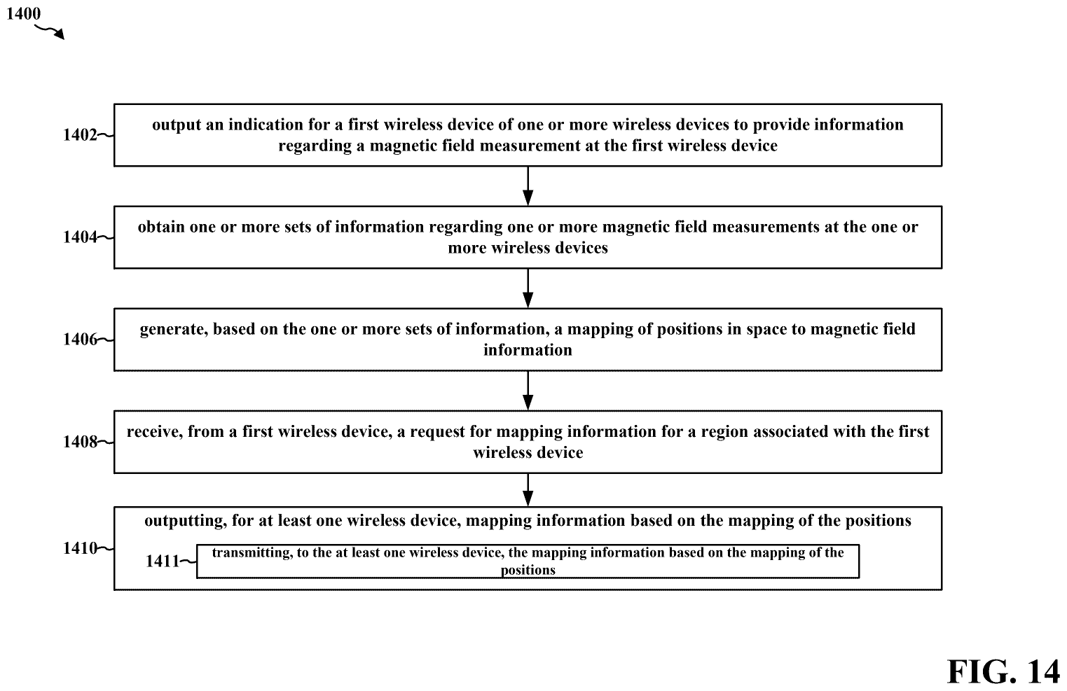

FIG. 14 is a flowchart 1400 of a method of wireless communication. The method may be performed by a network device such as a network node or a base station (e.g., the base station 102, 702, 802, 902; the network entity 1502, 1602, 1760). At 1402, the network node may output an indication for a first wireless device of one or more wireless devices to provide information regarding a magnetic field measurement at the first wireless device. For example, 1402 may be performed by CU processor(s) 1612, DU processor(s) 1632, RU processor(s) 1642, transceiver(s) 1646, antenna(s) 1680, network processor 1712, network interface 1780, and/or magnetic field mapping component 199 of FIGS. 16 and 17. The indication, in some aspects, may include an indication of one or more triggering events or criteria for providing magnetic field measurement information to the network device. The indication for the first wireless device to provide (or transmit) magnetic field measurement information, in some aspects, may indicate time-based criteria (e.g., associated with a period defined in terms of slots, a SFN, or other unit of time or associated with a set of indicated times). In some aspects, the indication for the first wireless device to provide (or transmit) magnetic field measurement information may indicate displacement-based criteria (e.g., associated with a displacement of 1 cm, 1 dm, 1 m, or other fixed distance in two or three dimensions). The indication for the first wireless device to provide (or transmit) magnetic field measurement information, in some aspects, may indicate event-based criteria (e.g., based on detecting an abnormality, based on transitioning into (or out of) an abnormal region, based on receiving a request to provide magnetic field information). In some aspects, an indication (or request) to provide magnetic field information may be associated with an indicated location and/or time at which to transmit the magnetic field information. For example, referring to FIGS. 7 and 8, the base station 702 (or 802) may transmit a magnetic field reporting configuration 708 (or 808).

At 1404, the network device may obtain one or more sets of information regarding one or more magnetic field measurements at one or more wireless devices. For example, 1404 may be performed by CU processor(s) 1612, DU processor(s) 1632, RU processor(s) 1642, transceiver(s) 1646, antenna(s) 1680, network processor 1712, network interface 1780, and/or magnetic field mapping component 199 of FIGS. 16 and 17. A set of information in the one or more sets of information regarding one or more magnetic field measurements at the one or more wireless devices (e.g., regarding the location of the wireless device and the measured magnetic field at the location of the wireless device), in some aspects, may include at least one of first information regarding a strength and a direction of the magnetic field measured by a wireless device, second information regarding a sensor of the wireless device used to measure the magnetic field, third information regarding an orientation of the wireless device while measuring the magnetic field, and/or fourth information regarding a time associated with measuring the magnetic field. The first information may be provided as a vector (e.g., in Cartesian or polar coordinates). The information regarding one or more magnetic field measurements at one or more wireless devices (e.g., information regarding the location of the wireless device and the measured magnetic field at the location of the wireless device), in some aspects, may be raw measurement data or calibrated measurement data. In some aspects, the information regarding the location of the wireless device and the measured magnetic field at the location of the wireless device may include an indication of whether the magnetic sensor has been saturated (e.g., whether the magnetic field is at least as strong as the strongest magnetic field measurable by the sensor). For example, referring to FIGS. 7, 8, and 9, the base station 702 (or 802 or 902) may receive, magnetic field measurement information 718 (or 818, 824, or 918) (e.g., information regarding the location of the wireless device and the measured magnetic field at the location of the wireless device) from the plurality of UEs 804.

At 1406, the network device may generate, based on the one or more sets of information, a mapping of positions in space to magnetic field information. For example, 1406 may be performed by CU processor(s) 1612, DU processor(s) 1632, RU processor(s) 1642, transceiver(s) 1646, antenna(s) 1680, network processor 1712, network interface 1780, and/or magnetic field mapping component 199 of FIGS. 16 and 17. The magnetic field mapping generated at 1406, in some aspects, may include at least one of a first mapping of magnetic field vectors to spatial positions (e.g., as depicted by magnetic field difference vector 652 or magnetic field vectors 611, 631, 651, or 661 of FIG. 6) or a second mapping identifying a first region associated with a magnetic field that is not consistent with a first known magnetic field for at least one second region including the first region (e.g., as depicted in diagram 600 in relation to subregions 630, 640, 650A, 650B, or 660 as opposed to subregions 610 and 625 within the first region). For example, referring to FIG. 8, the base station 802 may, at 820 magnetic field mapping (e.g., a mapping of positions in space to magnetic field information).

At 1408, the network device may receive, from a first wireless device, a request for the mapping information for a region associated with the first wireless device. For example, 1408 may be performed by CU processor(s) 1612, DU processor(s) 1632, RU processor(s) 1642, transceiver(s) 1646, antenna(s) 1680, network processor 1712, network interface 1780, and/or magnetic field mapping component 199 of FIGS. 16 and 17. Referring to FIG. 9, for example, the base station 902 may receive a magnetic field mapping data request 915.

At 1410, the network device may output, for at least one wireless device (e.g., the first wireless device), mapping information based on the mapping of the positions in space to magnetic field information. In some aspects, outputting the mapping information may include transmitting, at 1411 based on the request received at 1408, the mapping information based on the mapping of the positions in space to magnetic field information. For example, 1410 and 1411 may be performed by CU processor(s) 1612, DU processor(s) 1632, RU processor(s) 1642, transceiver(s) 1646, antenna(s) 1680, network processor 1712, network interface 1780, and/or magnetic field mapping component 199 of FIGS. 16 and 17. In some aspects, the network may determine to output the mapping of the positions in space to magnetic field information to the first wireless device in response to identifying that the first wireless device has transitioned between regions and/or that a current region associated with the first wireless device has an updated status (switching from normal to abnormal or vice versa). The mapping information, in some aspects, may be the mapping information generated at 1406.

FIG. 15 is a diagram 1500 illustrating an example of a hardware implementation for an apparatus 1504. The apparatus 1504 may be a UE, a component of a UE, or may implement UE functionality. In some aspects, the apparatus 1504 may include at least one cellular baseband processor 1524 (also referred to as a modem) coupled to one or more transceivers 1522 (e.g., cellular RF transceiver). The cellular baseband processor(s) 1524 may include at least one on-chip memory 1524′. In some aspects, the apparatus 1504 may further include one or more subscriber identity modules (SIM) cards 1520 and at least one application processor 1506 coupled to a secure digital (SD) card 1508 and a screen 1510. The application processor(s) 1506 may include on-chip memory 1506′. In some aspects, the apparatus 1504 may further include a Bluetooth module 1512, a WLAN module 1514, an SPS module 1516 (e.g., GNSS module), one or more sensor modules 1518 (e.g., barometric pressure sensor/altimeter; motion sensor such as inertial measurement unit (IMU), gyroscope, and/or accelerometer(s); light detection and ranging (LIDAR), radio assisted detection and ranging (RADAR), sound navigation and ranging (SONAR), magnetometer, audio and/or other technologies used for positioning), additional memory modules 1526, a power supply 1530, and/or a camera 1532. The Bluetooth module 1512, the WLAN module 1514, and the SPS module 1516 may include an on-chip transceiver (TRX) (or in some cases, just a receiver (RX)). The Bluetooth module 1512, the WLAN module 1514, and the SPS module 1516 may include their own dedicated antennas and/or utilize one or more antennas 1580 for communication. The cellular baseband processor(s) 1524 communicates through the transceiver(s) 1522 via the one or more antennas 1580 with the UE 104 and/or with an RU associated with a network entity 1502. The cellular baseband processor(s) 1524 and the application processor(s) 1506 may each include a computer-readable medium/memory 1524′, 1506′, respectively. The additional memory modules 1526 may also be considered a computer-readable medium/memory. Each computer-readable medium/memory 1524′, 1506′, 1526 may be non-transitory. The cellular baseband processor(s) 1524 and the application processor(s) 1506 are each responsible for general processing, including the execution of software stored on the computer-readable medium/memory. The software, when executed by the cellular baseband processor(s) 1524/application processor(s) 1506, causes the cellular baseband processor(s) 1524/application processor(s) 1506 to perform the various functions described supra. The computer-readable medium/memory may also be used for storing data that is manipulated by the cellular baseband processor(s) 1524/application processor(s) 1506 when executing software. The cellular baseband processor(s) 1524/application processor(s) 1506 may be a component of the UE 350 and may include the at least one memory 360 and/or at least one of the TX processor 368, the RX processor 356, and the controller/processor 359. In one configuration, the apparatus 1504 may be at least one processor chip (modem and/or application) and include just the cellular baseband processor(s) 1524 and/or the application processor(s) 1506, and in another configuration, the apparatus 1504 may be the entire UE (e.g., see UE 350 of FIG. 3) and include the additional modules of the apparatus 1504.

As discussed supra, the magnetic field reporting component 198 may be configured to obtain an indication of a location of the wireless device, measure a magnetic field at the location of the wireless device, and output, for a network device, information regarding the location of the wireless device and the measured magnetic field at the location of the wireless device. The magnetic field reporting component 198 may be within the cellular baseband processor(s) 1524, the application processor(s) 1506, or both the cellular baseband processor(s) 1524 and the application processor(s) 1506. The magnetic field reporting component 198 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. As shown, the apparatus 1504 may include a variety of components configured for various functions. In one configuration, the apparatus 1504, and in particular the cellular baseband processor(s) 1524 and/or the application processor(s) 1506, may include means for obtaining an indication of a location of the wireless device. The apparatus 1504, and in particular the cellular baseband processor(s) 1524 and/or the application processor(s) 1506, in some aspects, may include means for measuring a magnetic field at the location of the wireless device. The apparatus 1504, and in particular the cellular baseband processor(s) 1524 and/or the application processor(s) 1506, in some aspects, may include means for outputting, for a network device, information regarding the location of the wireless device and the measured magnetic field at the location of the wireless device. The apparatus 1504, and in particular the cellular baseband processor(s) 1524 and/or the application processor(s) 1506, in some aspects, may include means for obtaining a mapping of magnetic field information to a set of spatial positions. The apparatus 1504, and in particular the cellular baseband processor(s) 1524 and/or the application processor(s) 1506, in some aspects, may include means for determining a position of the wireless device using the mapping of the magnetic field information to the set of spatial positions. The apparatus 1504, and in particular the cellular baseband processor(s) 1524 and/or the application processor(s) 1506, in some aspects, may include means for omitting the measured magnetic field at the wireless device based on the mapping identifying the first region. The apparatus 1504, and in particular the cellular baseband processor(s) 1524 and/or the application processor(s) 1506, in some aspects, may include means for using the magnetic field at the wireless device and the mapping. The apparatus 1504, and in particular the cellular baseband processor(s) 1524 and/or the application processor(s) 1506, in some aspects, may include means for using the mapping and a plurality of measurements of the magnetic field at the wireless device associated with a corresponding plurality of times to determine a current position. The apparatus 1504, and in particular the cellular baseband processor(s) 1524 and/or the application processor(s) 1506, in some aspects, may include means for detecting at least one of a first difference between the measured magnetic field and a first known magnetic field with a first magnitude larger than a first threshold value or a second difference between a first orientation based on at least one other sensor and a second orientation based on the first known magnetic field with a second magnitude that is larger than a second threshold value. The apparatus 1504, and in particular the cellular baseband processor(s) 1524 and/or the application processor(s) 1506, in some aspects, may include means for transmitting, to the network device, the information regarding the location of the wireless device and the measured magnetic field at the location of the wireless device. The apparatus 1504, and in particular the cellular baseband processor(s) 1524 and/or the application processor(s) 1506, in some aspects, may include means for determining the location of the wireless device. The apparatus 1504, and in particular the cellular baseband processor(s) 1524 and/or the application processor(s) 1506, in some aspects, may include means for receiving, from the network device, the indication of the location of the wireless device. The means may be the magnetic field reporting component 198 of the apparatus 1504 configured to perform the functions recited by the means. As described supra, the apparatus 1504 may include the TX processor 368, the RX processor 356, and the controller/processor 359. As such, in one configuration, the means may be the TX processor 368, the RX processor 356, and/or the controller/processor 359 configured to perform the functions recited by the means or as described in relation to FIGS. 11 and 12.

FIG. 16 is a diagram 1600 illustrating an example of a hardware implementation for a network entity 1602. The network entity 1602 may be a BS, a component of a BS, or may implement BS functionality. The network entity 1602 may include at least one of a CU 1610, a DU 1630, or an RU 1640. For example, depending on the layer functionality handled by the magnetic field mapping component 199, the network entity 1602 may include the CU 1610; both the CU 1610 and the DU 1630; each of the CU 1610, the DU 1630, and the RU 1640; the DU 1630; both the DU 1630 and the RU 1640; or the RU 1640. The CU 1610 may include at least one CU processor 1612. The CU processor(s) 1612 may include on-chip memory 1612′. In some aspects, the CU 1610 may further include additional memory modules 1614 and a communications interface 1618. The CU 1610 communicates with the DU 1630 through a midhaul link, such as an F1 interface. The DU 1630 may include at least one DU processor 1632. The DU processor(s) 1632 may include on-chip memory 1632′. In some aspects, the DU 1630 may further include additional memory modules 1634 and a communications interface 1638. The DU 1630 communicates with the RU 1640 through a fronthaul link. The RU 1640 may include at least one RU processor 1642. The RU processor(s) 1642 may include on-chip memory 1642′. In some aspects, the RU 1640 may further include additional memory modules 1644, one or more transceivers 1646, one or more antennas 1680, and a communications interface 1648. The RU 1640 communicates with the UE 104. The on-chip memory 1612′, 1632′, 1642′ and the additional memory modules 1614, 1634, 1644 may each be considered a computer-readable medium/memory. Each computer-readable medium/memory may be non-transitory. Each of the processors 1612, 1632, 1642 is responsible for general processing, including the execution of software stored on the computer-readable medium/memory. The software, when executed by the corresponding processor(s) causes the processor(s) to perform the various functions described supra. The computer-readable medium/memory may also be used for storing data that is manipulated by the processor(s) when executing software.

As discussed supra, the magnetic field mapping component 199 may be configured to obtain one or more sets of information regarding one or more magnetic field measurements at one or more wireless devices, generate, based on the one or more sets of information, a mapping of positions in space to magnetic field information, and output, for at least one wireless device, mapping information based on the mapping of the positions. The magnetic field mapping component 199 may be within one or more processors of one or more of the CU 1610, DU 1630, and the RU 1640. The magnetic field mapping component 199 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. The network entity 1602 may include a variety of components configured for various functions. In one configuration, the network entity 1602 may include means for obtaining one or more sets of information regarding one or more magnetic field measurements at one or more wireless devices. The network entity 1602, in some aspects, may include means for generating, based on the one or more sets of information, a mapping of positions in space to magnetic field information. The network entity 1602, in some aspects, may include means for outputting, for at least one wireless device, mapping information based on the mapping of the positions. The network entity 1602, in some aspects, may include means for outputting an indication for a first wireless device of the one or more wireless devices to provide information regarding a magnetic field measurement at the first wireless device. The network entity 1602, in some aspects, may include means for receiving, from a first wireless device, a request for the mapping information for a region associated with the first wireless device. The network entity 1602, in some aspects, may include means for transmitting, to the at least one wireless device, the mapping information based on the mapping of the positions. The means may be the magnetic field mapping component 199 of the network entity 1602 configured to perform the functions recited by the means. As described supra, the network entity 1602 may include the TX processor 316, the RX processor 370, and the controller/processor 375. As such, in one configuration, the means may be the TX processor 316, the RX processor 370, and/or the controller/processor 375 configured to perform the functions recited by the means or as described in relation to FIGS. 13 and 14.

FIG. 17 is a diagram 1700 illustrating an example of a hardware implementation for a network entity 1760. In one example, the network entity 1760 may be within the core network 120. The network entity 1760 may include at least one network processor 1712. The network processor(s) 1712 may include on-chip memory 1712′. In some aspects, the network entity 1760 may further include additional memory modules 1714. The network entity 1760 communicates via the network interface 1780 directly (e.g., backhaul link) or indirectly (e.g., through a RIC) with the CU 1702. The on-chip memory 1712′ and the additional memory modules 1714 may each be considered a computer-readable medium/memory. Each computer-readable medium/memory may be non-transitory. The network processor(s) 1712 is responsible for general processing, including the execution of software stored on the computer-readable medium/memory. The software, when executed by the corresponding processor(s) causes the processor(s) to perform the various functions described supra. The computer-readable medium/memory may also be used for storing data that is manipulated by the processor(s) when executing software.

As discussed supra, the magnetic field mapping component 199 may be configured to obtain one or more sets of information regarding one or more magnetic field measurements at one or more wireless devices, generate, based on the one or more sets of information, a mapping of positions in space to magnetic field information, and output, for at least one wireless device, mapping information based on the mapping of the positions. The magnetic field mapping component 199 may be within the network processor(s) 1712. The magnetic field mapping component 199 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. The network entity 1760 may include a variety of components configured for various functions. In one configuration, the network entity 1760 may include means for obtaining one or more sets of information regarding one or more magnetic field measurements at one or more wireless devices. The network entity 1760, in some aspects, may include means for generating, based on the one or more sets of information, a mapping of positions in space to magnetic field information. The network entity 1760, in some aspects, may include means for outputting, for at least one wireless device, mapping information based on the mapping of the positions. The network entity 1760, in some aspects, may include means for outputting an indication for a first wireless device of the one or more wireless devices to provide information regarding a magnetic field measurement at the first wireless device. The network entity 1760, in some aspects, may include means for receiving, from a first wireless device, a request for the mapping information for a region associated with the first wireless device. The network entity 1760, in some aspects, may include means for transmitting, to the at least one wireless device, the mapping information based on the mapping of the positions. The means may be the magnetic field mapping component 199 of the network entity 1760 configured to perform the functions recited by the means or as described in relation to FIGS. 13 and 14.

A wireless device, in some aspects, may include an inertial measurement unit (IMU) used in determining a location and orientation of the device. A magnetometer, in some aspects, may be a component of the IMU and may provide the magnetic north (or south) direction. Combined with other measurements, the mobile device may estimate its orientation and or positioning using sensor fusion (e.g., Kalman filtering). Given a rough location estimation, a wireless device or UE may retrieve its local magnetic field from a database and take its direction as the magnetic north direction. In a complex environment with many magnetic materials, the local magnetic field will be distorted and won't match the database one.

In an open space, this usually works well. However, in a complex environment with many magnetic materials, the local magnetic field may be distorted and may not match the magnetic field direction indicated in the database. This will cause orientation and/or positioning errors. For example, a sensor fusion algorithm may not converge and may trigger a warning regarding an unreliability and/or a large uncertainty of an associated orientation and/or positioning determination. Therefore, a high resolution magnetic field database may provide for robust sensor fusion (e.g., for orientation estimation and/or positioning) in a complex environment (e.g., in an indoor office).

Various aspects relate generally to reporting magnetic field information from one or more wireless devices to a network device for the network device to generate a high resolution magnetic field database that can be used by the wireless device to perform an orientation and/or positioning operation. In one embodiment, we propose a high resolution magnetic field database for robust sensor fusion. The magnetic field map is crowd sourced from UEs, and maintained by the network. UEs can then use the magnetic field map for orientation/positioning. Furthermore, improved positioning can be obtained with trajectory tracking through magnetic field as fingerprinting. Some aspects more specifically relate to a wireless device that obtains an indication of a location of the wireless device, measures a magnetic field at the location of the wireless device, and outputs, for a network device, information regarding the location of the wireless device and the measured magnetic field at the location of the wireless device. Some aspects relate to a network device that obtains one or more sets of information regarding one or more magnetic field measurements at one or more wireless devices, generates, based on the one or more sets of information, a mapping of positions in space to magnetic field information, and outputs, for at least one wireless device, mapping information based on the mapping of the positions.

Particular aspects of the subject matter described in this disclosure can be implemented to realize one or more of the following potential advantages. In some examples, by providing magnetic field information from at least one wireless device to a network device and generating and/or providing a mapping of the magnetic field to one or more wireless devices, the described techniques can be used to improve the accuracy of an orientation and/or positioning operation.

It is understood that the specific order or hierarchy of blocks in the processes/flowcharts disclosed is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not limited to the aspects described herein, but are to be accorded the full scope consistent with the language claims. Reference to an element in the singular does not mean “one and only one” unless specifically so stated, but rather “one or more.” Terms such as “if,” “when,” and “while” do not imply an immediate temporal relationship or reaction. That is, these phrases, e.g., “when,” do not imply an immediate action in response to or during the occurrence of an action, but simply imply that if a condition is met then an action will occur, but without requiring a specific or immediate time constraint for the action to occur. The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. Sets should be interpreted as a set of elements where the elements number one or more. Accordingly, for a set of X, X would include one or more elements. When at least one processor is configured to perform a set of functions, the at least one processor, individually or in any combination, is configured to perform the set of functions. Accordingly, each processor of the at least one processor may be configured to perform a particular subset of the set of functions, where the subset is the full set, a proper subset of the set, or an empty subset of the set. A processor may be referred to as processor circuitry. A memory/memory module may be referred to as memory circuitry. If a first apparatus receives data from or transmits data to a second apparatus, the data may be received/transmitted directly between the first and second apparatuses, or indirectly between the first and second apparatuses through a set of apparatuses. A device configured to “output” data, such as a transmission, signal, or message, may transmit the data, for example with a transceiver, or may send the data to a device that transmits the data. A device configured to “obtain” data, such as a transmission, signal, or message, may receive, for example with a transceiver, or may obtain the data from a device that receives the data. Information stored in a memory includes instructions and/or data. All structural and functional equivalents to the elements of the various aspects described throughout this disclosure that are known or later come to be known to those of ordinary skill in the art are expressly incorporated herein by reference and are encompassed by the claims. Moreover, nothing disclosed herein is dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

As used herein, the phrase “based on” shall not be construed as a reference to a closed set of information, one or more conditions, one or more factors, or the like. In other words, the phrase “based on A” (where “A” may be information, a condition, a factor, or the like) shall be construed as “based at least on A” unless specifically recited differently.

The following aspects are illustrative only and may be combined with other aspects or teachings described herein, without limitation.

Aspect 1 is a method of wireless communication at a wireless device, comprising: obtaining an indication of a location of the wireless device; measuring a magnetic field at the location of the wireless device; and outputting, for a network device, information regarding the location of the wireless device and the measured magnetic field at the location of the wireless device.

Aspect 2 is the method of aspect 1, further comprising: obtaining a mapping of magnetic field information to a set of spatial positions; and determining a position of the wireless device using the mapping of the magnetic field information to the set of spatial positions.

Aspect 3 is the method of aspect 2, wherein the mapping of the magnetic field information to the set of spatial positions comprises at least one of a first mapping of magnetic field vectors to the set of spatial positions or a second mapping identifying a first region associated with at least one magnetic field that is not consistent with a first known magnetic field for at least one second region including the first region.

Aspect 4 is the method of aspect 3, wherein determining the position of the wireless device comprises: omitting the measured magnetic field at the wireless device based on the mapping identifying the first region; or using the magnetic field at the wireless device and the mapping.

Aspect 5 is the method of any of aspects 2 to 4, wherein determining the position of the wireless device comprises using the mapping and a plurality of measurements of the magnetic field at the wireless device associated with a corresponding plurality of times to determine a current position.

Aspect 6 is the method of any of aspects 1 to 5, wherein the information regarding the measured magnetic field at the wireless device is related to at least one of a raw magnetic field measurement and a calibrated magnetic field measurement.

Aspect 7 is the method of any of aspects 1 to 6, wherein the information regarding the measured magnetic field at the wireless device is associated with at least one of a set of three independent axes and a set of polar coordinates.

Aspect 8 is the method of any of aspects 1 to 7, wherein the information regarding the magnetic field measured at the wireless device comprises at least one of first information regarding a strength and a direction of the magnetic field at the wireless device, second information regarding a sensor of the wireless device used to measure the magnetic field at the wireless device, third information regarding an orientation of the wireless device while measuring the magnetic field at the wireless device, and fourth information regarding a time associated with measuring the magnetic field at the wireless device.

Aspect 9 is the method of any of aspects 1 to 8, wherein outputting the information regarding the location of the wireless device and the measured magnetic field at the location of the wireless device is based on at least one of detecting an anomaly in the magnetic field at the wireless device, a configured periodicity, or a request to output the information.

Aspect 10 is the method of aspect 9, wherein detecting the anomaly in the magnetic field at the wireless device comprises detecting at least one of a first difference between the measured magnetic field and a first known magnetic field with a first magnitude larger than a first threshold value or a second difference between a first orientation based on at least one other sensor and a second orientation based on the first known magnetic field with a second magnitude that is larger than a second threshold value.

Aspect 11 is the method of any of aspects 1 to 10, wherein outputting the information regarding the location of the wireless device and the measured magnetic field at the location of the wireless device comprises: transmitting, to the network device, the information regarding the location of the wireless device and the measured magnetic field at the location of the wireless device.

Aspect 12 is the method of any of aspects 1 to 11, wherein obtaining the indication of the location of the wireless device comprises one of: determining the location of the wireless device; or receiving, from the network device, the indication of the location of the wireless device.

Aspect 13 is a method of wireless communication at a network device, comprising: obtaining one or more sets of information regarding one or more magnetic field measurements at one or more wireless devices; generating, based on the one or more sets of information, a mapping of positions in space to magnetic field information; and outputting, for at least one wireless device, mapping information based on the mapping of the positions.

Aspect 14 is the method of aspect 13, wherein the mapping of the positions in space to the magnetic field information comprises at least one of a first mapping of magnetic field vectors to spatial positions or a second mapping identifying a first region associated with a magnetic field that is not consistent with a first known magnetic field for at least one second region including the first region.

Aspect 15 is the method of any of aspects 13 and 14, further comprising: outputting an indication for a first wireless device of the one or more wireless devices to provide information regarding a magnetic field measurement at the first wireless device.

Aspect 16 is the method of aspect 15, wherein outputting the indication is based on obtaining at least one set of information regarding at least one magnetic field measurement in a region associated with the first wireless device that is inconsistent with a first known magnetic field.

Aspect 17 is the method of any of aspects 15 and 16, wherein the indication for the first wireless device to provide the information comprises at least one of a first indication to provide the information regarding a current time, a second indication to provide the information regarding a scheduled future time, or a third indication to provide the information regarding a future time associated with a detection of a difference between a measured magnetic field and a first known magnetic field that is larger than a first threshold value.

Aspect 18 is the method of any of aspects 13 to 17, further comprising: receiving, from a first wireless device, a request for the mapping information for a region associated with the first wireless device, wherein outputting the mapping information is based on the request and comprises correction data for the region.

Aspect 19 is the method of any of aspects 13 to 18, wherein the one or more sets of information regarding the one or more magnetic field measurements at the one or more wireless devices is related to at least one of one or more raw magnetic field measurements or one or more calibrated magnetic field measurements.

Aspect 20 is the method of any of aspects 13 to 19, wherein the one or more sets of information regarding the one or more magnetic field measurements at the one or more wireless devices is associated with at least one of a set of three independent axes and a set of polar coordinates.

Aspect 21 is the method of any of aspects 13 to 20, wherein the one or more sets of information regarding the one or more magnetic field measurements at the one or more wireless devices comprises at least one of first information regarding a strength and a direction of one or more magnetic fields measured at the one or more wireless devices, second information regarding one or more sensors of the one or more wireless devices used to measure the one or more magnetic fields at the one or more wireless devices, third information regarding one or more positions of the one or more wireless devices while performing the one or more magnetic field measurements, fourth information regarding one or more orientations of the one or more wireless devices while performing the one or more magnetic field measurements, and fifth information regarding one or more times associated with performing the one or more magnetic field measurements.

Aspect 22 is the method of any of aspects 13 to 21, wherein outputting the mapping information based on the mapping of the positions comprises: transmitting, to the at least one wireless device, the mapping information based on the mapping of the positions.

Aspect 23 is an apparatus for wireless communication at a device including a memory and at least one processor coupled to the memory and, based at least in part on information stored in the memory, the at least one processor is configured to implement any of aspects 1 to 12.

Aspect 24 is the apparatus of aspect 23, further including a transceiver or an antenna coupled to the at least one processor.

Aspect 25 is an apparatus for wireless communication at a device including means for implementing any of aspects 1 to 12.

Aspect 26 is a computer-readable medium (e.g., a non-transitory computer-readable medium) storing computer executable code, where the code when executed by a processor causes the processor to implement any of aspects 1 to 12.

Aspect 27 is an apparatus for wireless communication at a device including a memory and at least one processor coupled to the memory and, based at least in part on information stored in the memory, the at least one processor is configured to implement any of aspects 13 to 22

Aspect 28 is the apparatus of aspect 27, further including a transceiver or an antenna coupled to the at least one processor.

Aspect 29 is an apparatus for wireless communication at a device including means for implementing any of aspects 13 to 22.

Aspect 30 is a computer-readable medium (e.g., a non-transitory computer-readable medium) storing computer executable code, where the code when executed by a processor causes the processor to implement any of aspects 13 to 22.

What is claimed is:

1. An apparatus for wireless communication at a wireless device, comprising:
at least one memory; and
at least one processor coupled to the at least one memory and, based at least in part on stored information that is stored in the at least one memory, the at least one processor, individually or in any combination, is configured to:
obtain an indication of a location of the wireless device;
measure a magnetic field at the location of the wireless device; and
output, for a network device, information regarding the location of the wireless device and the measured magnetic field at the location of the wireless device.

2. The apparatus of claim 1, wherein the at least one processor, individually or in any combination, is further configured to:
obtain a mapping of magnetic field information to a set of spatial positions; and
determine a position of the wireless device using the mapping of the magnetic field information to the set of spatial positions.

3. The apparatus of claim 2, wherein the mapping of the magnetic field information to the set of spatial positions comprises at least one of a first mapping of magnetic field vectors to the set of spatial positions or a second mapping identifying a first region associated with at least one magnetic field that is not consistent with a first known magnetic field for at least one second region including the first region.

4. The apparatus of claim 3, wherein to determine the position of the wireless device, the at least one processor, individually or in any combination, is configured to:
omit the measured magnetic field at the wireless device based on the mapping identifying the first region; or
use the magnetic field at the wireless device and the mapping.

5. The apparatus of claim 2, wherein to determine the position of the wireless device, the at least one processor, individually or in any combination, is configured to use the mapping and a plurality of measurements of the magnetic field at the wireless device associated with a corresponding plurality of times to determine a current position.

6. The apparatus of claim 1, wherein the information regarding the measured magnetic field at the wireless device is related to at least one of a raw magnetic field measurement and a calibrated magnetic field measurement.

7. The apparatus of claim 1, wherein the information regarding the measured magnetic field at the wireless device is associated with at least one of a set of three independent axes and a set of polar coordinates.

8. The apparatus of claim 1, wherein the information regarding the magnetic field measured at the wireless device comprises at least one of first information regarding a strength and a direction of the magnetic field at the wireless device, second information regarding a sensor of the wireless device used to measure the magnetic field at the wireless device, third information regarding an orientation of the wireless device while measuring the magnetic field at the wireless device, and fourth information regarding a time associated with measuring the magnetic field at the wireless device.

9. The apparatus of claim 1, wherein the at least one processor, individually or in any combination, is configured to output the information regarding the location of the wireless device and the measured magnetic field at the location of the wireless device based on at least one of detecting an anomaly in the magnetic field at the wireless device, a configured periodicity, or a request to output the information.

10. The apparatus of claim 9, wherein to detect the anomaly in the magnetic field at the wireless device, the at least one processor, individually or in any combination, is configured to detect at least one of a first difference between the measured magnetic field and a first known magnetic field with a first magnitude larger than a first threshold value or a second difference between a first orientation based on at least one other sensor and a second orientation based on the first known magnetic field with a second magnitude that is larger than a second threshold value.

11. The apparatus of claim 1, further comprising a transceiver coupled to the at least one processor, wherein to output the information regarding the location of the wireless device and the measured magnetic field at the location of the wireless device, the at least one processor, individually or in any combination, is configured to transmit, to the network device via the transceiver, the information regarding the location of the wireless device and the measured magnetic field at the location of the wireless device.

12. The apparatus of claim 1, wherein to obtain the indication of the location of the wireless device, the at least one processor, individually or in any combination, is configured to:
determine the location of the wireless device; or
receive, from the network device, the indication of the location of the wireless device.

13. An apparatus for wireless communication at a network device, comprising:
at least one memory; and
at least one processor coupled to the at least one memory and, based at least in part on stored information that is stored in the at least one memory, the at least one processor, individually or in any combination, is configured to:
obtain one or more sets of information regarding one or more magnetic field measurements at one or more wireless devices;
generate, based on the one or more sets of information, a mapping of positions in space to magnetic field information; and
output, for at least one wireless device, mapping information based on the mapping of the positions.

14. The apparatus of claim 13, wherein the mapping of the positions in space to the magnetic field information comprises at least one of a first mapping of magnetic field vectors to spatial positions or a second mapping identifying a first region associated with a magnetic field that is not consistent with a first known magnetic field for at least one second region including the first region.

15. The apparatus of claim 13, wherein the at least one processor, individually or in any combination, is further configured to:
output an indication for a first wireless device of the one or more wireless devices to provide information regarding a magnetic field measurement at the first wireless device.

16. The apparatus of claim 15, wherein the at least one processor, individually or in any combination, is configured to output the indication based on obtaining at least one set of information regarding at least one magnetic field measurement in a region associated with the first wireless device that is inconsistent with a first known magnetic field.

17. The apparatus of claim 15, wherein the indication for the first wireless device to provide the information comprises at least one of a first indication to provide the information regarding a current time, a second indication to provide the information regarding a scheduled future time, or a third indication to provide the information regarding a future time associated with a detection of a difference between a measured magnetic field and a first known magnetic field that is larger than a first threshold value.

18. The apparatus of claim 13, wherein the at least one processor, individually or in any combination, is further configured to:
receive, from a first wireless device, a request for the mapping information for a region associated with the first wireless device, wherein the at least one processor, individually or in any combination, is configured to output the mapping information based on the request and comprises correction data for the region.

19. The apparatus of claim 13, wherein the one or more sets of information regarding the one or more magnetic field measurements at the one or more wireless devices is related to at least one of one or more raw magnetic field measurements or one or more calibrated magnetic field measurements.

20. The apparatus of claim 13, wherein the one or more sets of information regarding the one or more magnetic field measurements at the one or more wireless devices is associated with at least one of a set of three independent axes and a set of polar coordinates.

21. The apparatus of claim 13, wherein the one or more sets of information regarding the one or more magnetic field measurements at the one or more wireless devices comprises at least one of first information regarding a strength and a direction of one or more magnetic fields measured at the one or more wireless devices, second information regarding one or more sensors of the one or more wireless devices used to measure the one or more magnetic fields at the one or more wireless devices, third information regarding one or more positions of the one or more wireless devices while performing the one or more magnetic field measurements, fourth information regarding one or more orientations of the one or more wireless devices while performing the one or more magnetic field measurements, and fifth information regarding one or more times associated with performing the one or more magnetic field measurements.

22. The apparatus of claim 13, further comprising a transceiver coupled to the at least one processor, wherein to output the mapping information based on the mapping of the positions, the at least one processor, individually or in any combination, is configured to transmit, to the at least one wireless device via the transceiver, the mapping information based on the mapping of the positions.

23. A method of wireless communication at a wireless device, comprising:
obtaining an indication of a location of the wireless device;
measuring a magnetic field at the location of the wireless device; and
outputting, for a network device, information regarding the location of the wireless device and the measured magnetic field at the location of the wireless device.

24. The method of claim 23, further comprising:
obtaining a mapping of magnetic field information to a set of spatial positions; and
determining a position of the wireless device using the mapping of the magnetic field information to the set of spatial positions.

25. The method of claim 24, wherein the mapping of the magnetic field information to the set of spatial positions comprises at least one of a first mapping of magnetic field vectors to the set of spatial positions or a second mapping identifying a first region associated with at least one magnetic field that is not consistent with a first known magnetic field for at least one second region including the first region.

26. The method of claim 24, wherein determining the position of the wireless device comprises using the mapping and a plurality of measurements of the magnetic field at the wireless device associated with a corresponding plurality of times to determine a current position.

27. A method of wireless communication at a network device, comprising:
obtaining one or more sets of information regarding one or more magnetic field measurements at one or more wireless devices;
generating, based on the one or more sets of information, a mapping of positions in space to magnetic field information; and
outputting, for at least one wireless device, mapping information based on the mapping of the positions.

28. The method of claim 27, wherein the mapping of the positions in space to the magnetic field information comprises at least one of a first mapping of magnetic field vectors to spatial positions or a second mapping identifying a first region associated with a magnetic field that is not consistent with a first known magnetic field for at least one second region including the first region.

29. The method of claim 27, further comprising:
outputting an indication for a first wireless device of the one or more wireless devices to provide information regarding a magnetic field measurement at the first wireless device, wherein the indication for the first wireless device to provide the information comprises at least one of a first indication to provide the information regarding a current time, a second indication to provide the information regarding a scheduled future time, or a third indication to provide the information regarding a future time associated with a detection of a difference between a measured magnetic field and a first known magnetic field that is larger than a first threshold value.

30. The method of claim 27, further comprising:
receiving, from a first wireless device, a request for the mapping information for a region associated with the first wireless device, wherein outputting the mapping information is based on the request and comprises correction data for the region.
